(19) United States
(12) Patent Application Publication
(10) Pub. No.: US 2026/0128064 A1
(43) Pub. Date: May 7, 2026

(54) SEMICONDUCTOR MEMORY DEVICE AND MANUFACTURING METHOD OF SEMICONDUCTOR MEMORY DEVICE

(71) Applicant: Kioxia Corporation, Tokyo (JP)

(72) Inventor: Hiromasa YOSHIMORI, Kawasaki (JP)

(73) Assignee: Kioxia Corporation, Tokyo (JP)

(21) Appl. No.: 19/077,440

(22) Filed: Mar. 12, 2025

(30) Foreign Application Priority Data
Nov. 7, 2024 (JP) 2024-195004

(51) Int. Cl. G11C 5/06; H01L 23/00; H01L 25/065; H10B 41/10; H10B 41/40; H10B 43/10; H10B 43/40; H10B 80/00; H10D 80/20

(52) U.S. Cl. CPC G11C 5/063; H10B 41/10; H10B 41/40; H10B 43/10; H10B 43/40; H10B 80/00; H10D 80/251; H10W 90/00; H10W 90/297; H10W 90/791

(57) ABSTRACT

According to one embodiment, a semiconductor memory device includes a first stacked body and a second stacked body in a first region. The semiconductor memory device includes a first via contact electrode in a second region adjacent to the first region and having a height that is at least half or more of a height of the first stacked body in the stacking direction, and a second via contact electrode disposed on the first via contact electrode in the stacking direction and electrically connected to the first via contact electrode and having a height that is at least half or more of the height of the second stacked body in the stacking direction. A diameter of a surface of the second via contact electrode facing the first via contact electrode is greater than a diameter of a surface of the first via contact electrode facing the second via contact electrode.

### CROSS-REFERENCE TO RELATED APPLICATION

This application is based upon and claims the benefit of priority from Japanese Patent Application No. 2024-195004, filed Nov. 7, 2024, the entire contents of which are incorporated herein by reference.

### FIELD

Embodiments described herein relate generally to a semiconductor memory device and a manufacturing method of the semiconductor memory device.

### BACKGROUND

A three-dimensional structured semiconductor memory device is proposed in which on a substrate, a memory hole is formed on a stacked body with a plurality of layers of wiring layers through the insulating layer, and a silicon body is provided in the memory hole. In addition, a technology is proposed to provide a control circuit of the memory cell array of the three-dimensional structure directly under or directly above the memory cell array.

### DESCRIPTION OF THE DRAWINGS

FIG. 1 is a block diagram illustrating an example of a configuration of a semiconductor memory device according to a first embodiment;

FIG. 2 is a perspective view illustrating an example of an appearance of the semiconductor memory device according to the first embodiment;

FIG. 3A is a cross-sectional view illustrating an example of a configuration of the semiconductor memory device according to the first embodiment;

FIG. 3B is a cross-sectional view illustrating an example of the configuration of the semiconductor memory device according to the first embodiment;

FIG. 4A is a cross-sectional view illustrating an example of the configuration of the semiconductor memory device according to the first embodiment;

FIG. 4B is a cross-sectional view illustrating an example of the configuration of the semiconductor memory device according to the first embodiment;

FIG. 4C is a cross-sectional view illustrating an example of the configuration of the semiconductor memory device according to the first embodiment;

FIG. 4D is a cross-sectional view illustrating an example of the configuration of the semiconductor memory device according to the first embodiment;

FIG. 5 is a cross-sectional view illustrating an example of a cross-sectional structure during manufacturing of a memory layer according to the first embodiment;

FIG. 6 is a cross-sectional view illustrating an example of a cross-sectional structure during manufacturing of the memory layer according to the first embodiment;

FIG. 7 is a cross-sectional view illustrating an example of a cross-sectional structure during manufacturing of the memory layer according to the first embodiment;

FIG. 8 is a cross-sectional view illustrating an example of a cross-sectional structure during manufacturing of the memory layer according to the first embodiment;

FIG. 9 is a cross-sectional view illustrating an example of a cross-sectional structure during manufacturing of the memory layer according to the first embodiment;

FIG. 10 is a cross-sectional view illustrating an example of a cross-sectional structure during manufacturing of the memory layer according to the first embodiment;

FIG. 11 is a cross-sectional view illustrating an example of a cross-sectional structure during manufacturing of the memory layer according to the first embodiment;

FIG. 12 is a cross-sectional view illustrating an example of a cross-sectional structure during manufacturing of the memory layer according to the first embodiment;

FIG. 13 is a cross-sectional view illustrating an example of a cross-sectional structure during manufacturing of the memory layer according to the first embodiment;

FIG. 14 is a cross-sectional view illustrating an example of a cross-sectional structure during manufacturing of the memory layer according to the first embodiment;

FIG. 15 is a cross-sectional view illustrating an example of a cross-sectional structure during manufacturing of the memory layer according to the first embodiment;

FIG. 16 is a cross-sectional view illustrating an example of a cross-sectional structure during manufacturing of a first CMOS layer according to the first embodiment;

FIG. 17 is a cross-sectional view illustrating an example of a cross-sectional structure during manufacturing of the first CMOS layer according to the first embodiment;

FIG. 18 is a cross-sectional view illustrating an example of a cross-sectional structure during manufacturing of the first CMOS layer according to the first embodiment;

FIG. 19 is a cross-sectional view illustrating an example of a bonding process of the memory layer and the first CMOS layer according to the first embodiment;

FIG. 20 is a cross-sectional view illustrating an example of the bonding process of the memory layer and the first CMOS layer according to the first embodiment;

FIG. 21 is a cross-sectional view illustrating an example of the bonding process of the memory layer and the first CMOS layer according to the first embodiment;

FIG. 22 is a cross-sectional view illustrating an example of the bonding process of the memory layer and the first CMOS layer according to the first embodiment;

FIG. 23 is a cross-sectional view illustrating an example of a bonding process of the first CMOS layer and a second CMOS layer according to the first embodiment;

FIG. 24 is a cross-sectional view illustrating an example of the bonding process of the first CMOS layer and the second CMOS layer according to the first embodiment;

FIG. 25 is a cross-sectional view illustrating an example of the bonding process of the first CMOS layer and the second CMOS layer according to the first embodiment;

FIG. 26 is a cross-sectional view illustrating an example of a configuration of the semiconductor memory device 1 according to a second embodiment;

FIG. 27 is a cross-sectional view illustrating an example of a cross-sectional structure during manufacturing of a memory layer according to the second embodiment;

FIG. 28 is a perspective view illustrating an example of an appearance of a semiconductor memory device according to a third embodiment;

FIG. 29 is a cross-sectional view illustrating an example of the configuration of the semiconductor memory device according to the third embodiment;

FIG. 30 is a cross-sectional view illustrating an example of a cross-sectional structure during manufacturing of a memory layer according to the third embodiment;

FIG. 31 is a cross-sectional view illustrating an example of a cross-sectional structure during manufacturing of the memory layer according to the third embodiment;

FIG. 32 is a cross-sectional view illustrating an example of a cross-sectional structure during manufacturing of the memory layer according to the third embodiment;

FIG. 33 is a cross-sectional view illustrating an example of a cross-sectional structure during manufacturing of the memory layer according to the third embodiment;

FIG. 34 is a cross-sectional view illustrating an example of the bonding process of the memory layer and a third CMOS layer according to the third embodiment;

FIG. 35 is a cross-sectional view illustrating an example of the bonding process of the memory layer and the third CMOS layer according to the third embodiment;

FIG. 36 is a cross-sectional view illustrating an example of the configuration of a semiconductor memory device according to a modification of the third embodiment;

FIG. 37 is a perspective view illustrating an example of an appearance of a semiconductor memory device according to a fourth embodiment;

FIG. 38 is a cross-sectional view illustrating an example of the configuration of the semiconductor memory device according to the fourth embodiment;

FIG. 39 is a cross-sectional view illustrating an example of a bonding process of a second memory layer and the first CMOS layer according to the fourth embodiment;

FIG. 40 is a cross-sectional view illustrating an example of the bonding process of the second memory layer and the first CMOS layer according to the fourth embodiment;

FIG. 41 is a cross-sectional view illustrating an example of the bonding process of the second memory layer and the first CMOS layer according to the fourth embodiment;

FIG. 42 is a cross-sectional view illustrating an example of the bonding process of the second memory layer and the first CMOS layer according to the fourth embodiment;

FIG. 43 is a cross-sectional view illustrating an example of the bonding process of the second memory layer and the memory layer according to the fourth embodiment;

FIG. 44 is a cross-sectional view illustrating an example of the bonding process of the second memory layer and the memory layer according to the fourth embodiment;

FIG. 45 is a cross-sectional view illustrating an example of the bonding process of the second memory layer and the memory layer according to the fourth embodiment;

FIG. 46 is a cross-sectional view illustrating an example of the bonding process of the second memory layer and the memory layer according to the fourth embodiment;

FIG. 47 is a cross-sectional view illustrating an example of the configuration of the semiconductor memory device according to the fourth embodiment;

FIG. 48 is a perspective view illustrating an example of an appearance of a semiconductor memory device according to a fifth embodiment;

FIG. 49 is a cross-sectional view illustrating an example of the configuration of the semiconductor memory device according to the fifth embodiment;

FIG. 50 is a cross-sectional view illustrating an example of a bonding process of a memory layer and a second memory layer according to the fifth embodiment;

FIG. 51 is a cross-sectional view illustrating an example of the bonding process of the memory layer and the second memory layer according to the fifth embodiment;

FIG. 52 is a cross-sectional view illustrating an example of the bonding process of the memory layer and the second memory layer according to the fifth embodiment;

FIG. 53 is a cross-sectional view illustrating an example of the bonding process of the second memory layer and a third CMOS layer according to the fifth embodiment;

FIG. 54 is a cross-sectional view illustrating an example of the bonding process of the second memory layer and the third CMOS layer according to the fifth embodiment;

FIG. 55 is a cross-sectional view illustrating an example of the bonding process of the second memory layer and the third CMOS layer according to the fifth embodiment; and

FIG. 56 is a cross-sectional view illustrating an example of the configuration of a semiconductor memory device according to a modification of the fifth embodiment.

### DETAILED DESCRIPTION

Embodiments provide a semiconductor memory device and a manufacturing method of the semiconductor memory device that can efficiently perform voltage supply.

In general, according to one embodiment, the semiconductor memory device includes a first stacked body in which a plurality of first conductive layers and a plurality of first insulating layers are alternately stacked in a first region, and a second stacked body disposed on the first stacked body in a stacking direction of the first stacked body, in which a plurality of second conductive layers and a plurality of second insulating layers are alternately stacked. Further, the semiconductor memory device includes a first via contact electrode disposed in a second region adjacent to the first region and having a height of at least half or more of the height in the stacking direction of the first stacked body, and a second via contact electrode disposed on the first via contact electrode in the stacking direction of the second region and electrically connected to the first via contact electrode and having a height of at least half or more of the height in a stacking direction of the second stacked body. The diameter of the surface facing the first via contact electrode at the second via contact electrode is greater than the diameter of the surface facing the second via contact electrode at the first via contact electrode.

Hereinafter, embodiments according to the present disclosure will be described with reference to the drawings. Embodiments are not intended to limit the present disclosure. The drawings are schematic or conceptual, and the ratio of each part, or the like is not necessarily the same as the actual one. The same elements as those described above with respect to the preceding drawings are given the same reference numerals in the specification and drawings, and detailed descriptions are omitted as appropriate.

### First Embodiment

The semiconductor memory device according to the first embodiment includes a memory cell and a CMOS circuit for accessing the memory cell. Thus, the semiconductor memory device has a structure in which the CMOS circuit is disposed on a plurality of substrates that are stacked. Hereinafter, details of the first embodiment will be described.

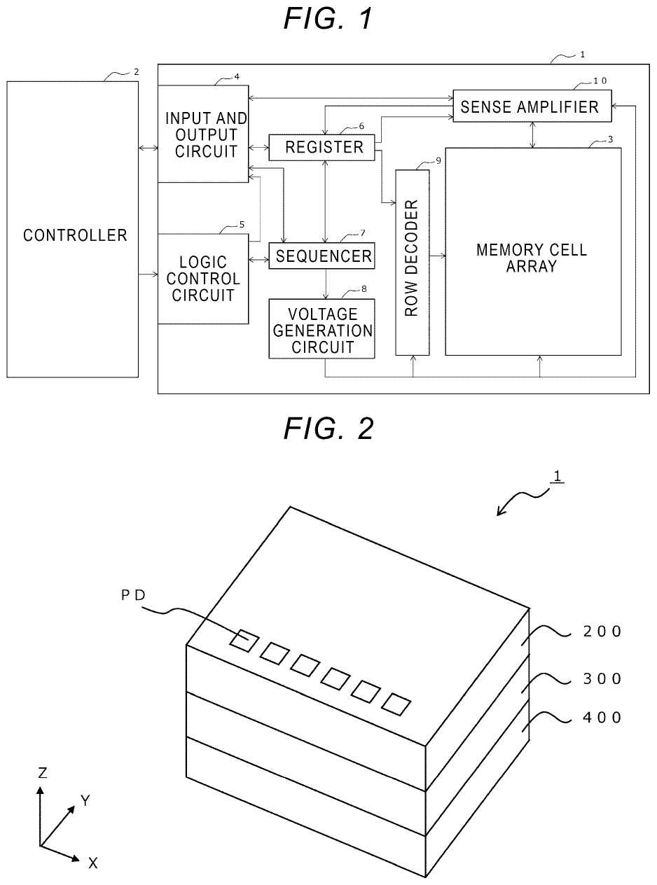

FIG. 1 is a block diagram illustrating an example of the configuration of a semiconductor memory device 1 according to the first embodiment. The semiconductor memory device 1 according to the present embodiment is controlled by an external controller 2. The semiconductor memory device 1 of the present embodiment is, for example, a NAND-type flash memory capable of storing data in a non-volatile manner.

The semiconductor memory device 1 includes, for example, a memory cell array 3, an input and output circuit 4, a logic control circuit 5, a register 6, a sequencer 7, a voltage generation circuit 8, a row decoder 9, and a sense amplifier 10.

The memory cell array 3 includes a plurality of non-volatile memory cells (not illustrated) associated with the word lines and the bit lines.

The input and output circuit 4 transmits and receives the signal DQ<7:0> (not illustrated), and the data strobe signals DQS and /QS to and from the controller 2. The input and output circuit 4 transfers the commands and addresses in the signal DQ<7:0> (not illustrated) to the register 6. Further, the input and output circuit 4 transmits and receives the written data and the read data to and from the sense amplifier 10.

The logic control circuit 5 receives a chip enable signal /CE, a command latch enable signal CLE, an address latch enable signal ALE, a write enable signal /WE, read enable signals RE and /RE, and a write protect signal /WP from the controller 2. Further, the logic control circuit 5 transmits a ready busy signal /RB to the controller 2 to notify the state of the semiconductor memory device 1 to the outside.

The voltage generation circuit 8 generates a voltage required for operations such as writing, reading, and erasing data based on the instructions from the sequencer 7.

The row decoder 9 receives the block address and the row address in the address from the register 6 and selects the corresponding block based on the block address and selects the corresponding word line based on the row address.

When reading data, the sense amplifier 10 senses the read data read from the memory cell to the bit line and transmits the sensed read data to the input and output circuit 4. When writing data, the sense amplifier 10 transmits written data written through the bit line to the memory cell.

FIG. 2 is a perspective view illustrating an example of the appearance of the semiconductor memory device 1 according to the first embodiment. The semiconductor memory device 1 has a structure in which a memory layer 200, a first CMOS layer 300, and a second CMOS layer 400 are stacked in order, for example, from top to bottom in the Z direction. The memory layer 200 is included, for example, in a first chip. The first CMOS layer 300 is included, for example, in a second chip. The second CMOS layer 400 is included, for example, in a third chip.

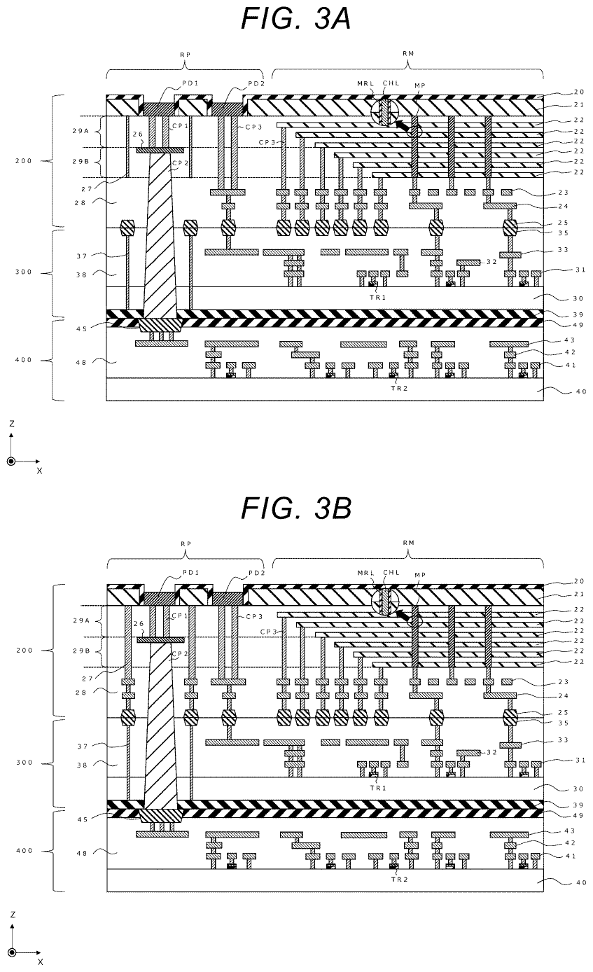

In the Z direction, the first CMOS layer 300 and the second CMOS layer 400 may each include, under the CMOS layer, a first substrate 30 and a second substrate 40 illustrated in FIG. 3 and the like, which are described below. In addition, the memory layer 200 may also have a wiring layer on the memory layer in the Z direction. It should be noted that the wiring layer in the memory layer 200 includes a layer formed on the memory after the bonding process of the memory layer 200 and the first CMOS layer 300 described below. The wiring layer includes, for example, a plurality of external pads PD used to connect the semiconductor memory device 1 and the controller 2. The external pad PD is connected to the input and output circuit 4 and is exposed on the surface of the semiconductor memory device 1.

The first CMOS layer 300 includes a CMOS circuit formed using a first substrate 30 (not illustrated). The second CMOS layer 400 includes a CMOS circuit formed using the second substrate 40 (not illustrated). A set including the first CMOS layer 300 and the second CMOS layer 400 includes, for example, the input and output circuit 4, the logic control circuit 5, the register 6, the sequencer 7, the voltage generation circuit 8, the row decoder 9, and the sense amplifier 10. The memory layer 200 includes the memory cell array 3. The second CMOS layer 400 includes a CMOS circuit that can perform a high-speed operation, for example. A CMOS circuit that performs a high-speed operation is, for example, the input and output circuit 4.

In the semiconductor memory device 1, the memory layer 200, the first CMOS layer 300, and the second CMOS layer 400 are bonded. At this time, each of the contact (boundary) portion between the memory layer 200 and the first CMOS layer 300 and the contact (boundary) portion between the first substrate 30 and the second CMOS layer 400 is a bonding surface. When the memory layer 200 and the first CMOS layer 300 are bonded, the memory cell array 3 in the memory layer 200 and the CMOS circuit in the first CMOS layer 300 may be sandwiched between the wiring layer and the first substrate 30. In addition, when the first substrate 30 and the second CMOS layer 400 are bonded, the CMOS circuit in the second CMOS layer 400 may be sandwiched between the first substrate 30 and the second substrate 40. Hereinafter, bonding of the memory layer 200 and the first CMOS layer 300 or bonding of the first CMOS layer 300 and the second CMOS layer 400 is referred to as a “bonding process”.

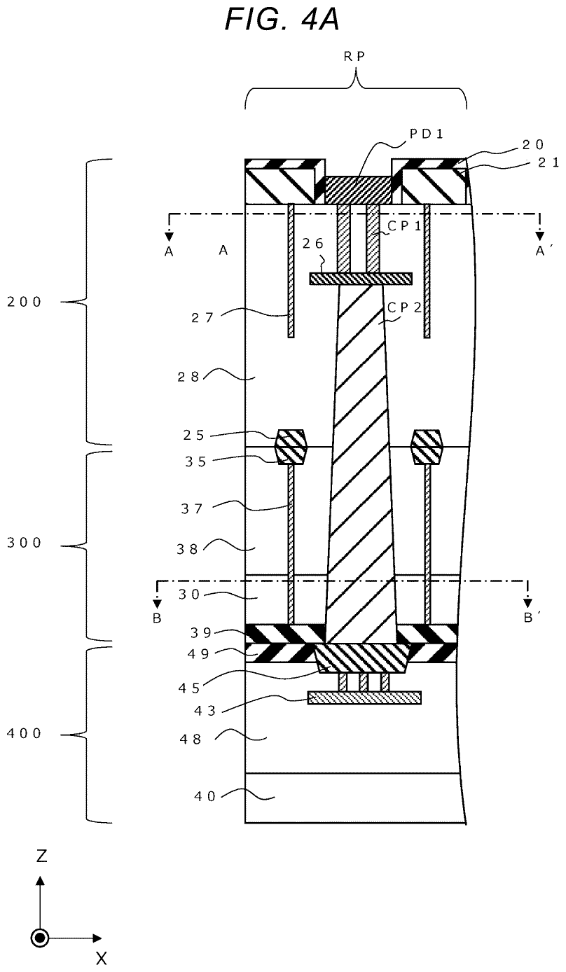

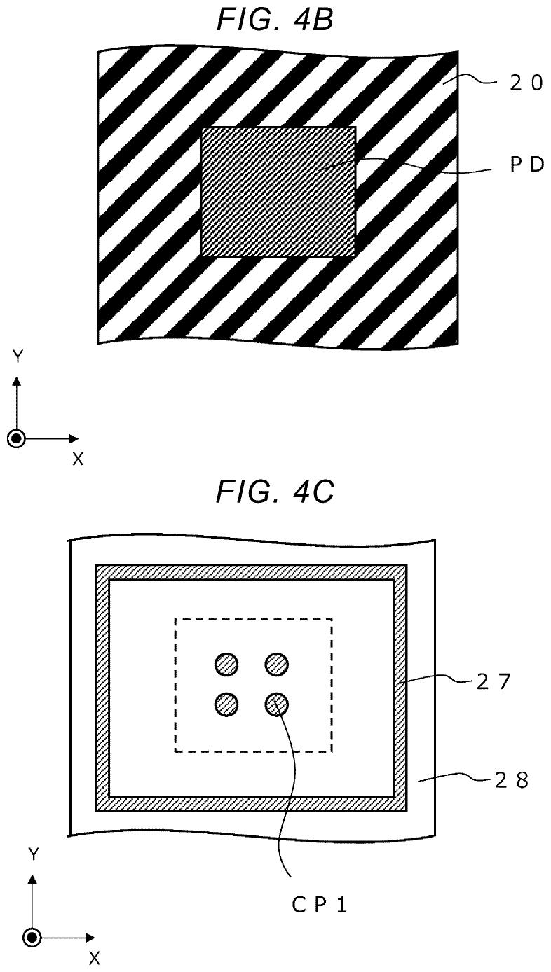

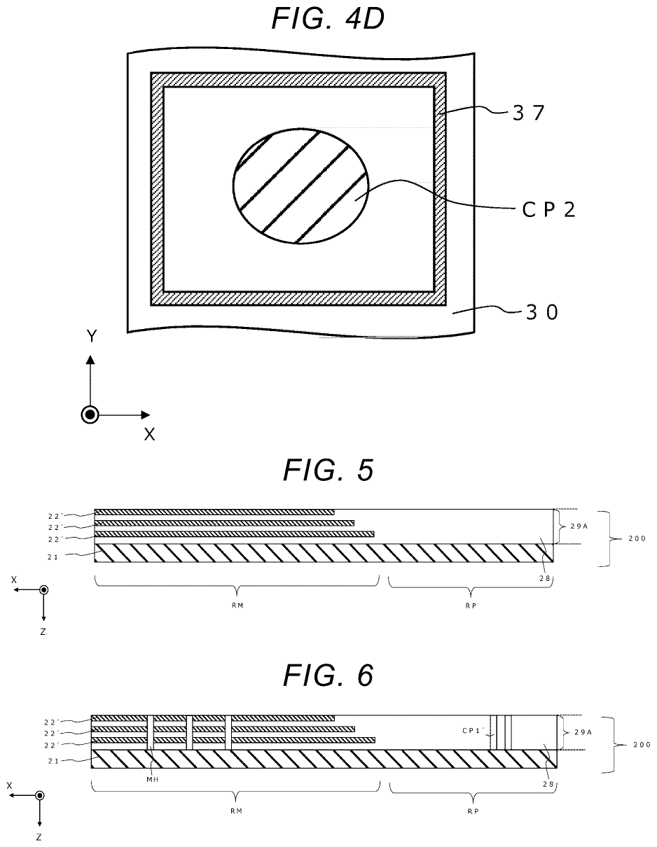

FIGS. 3A and 3B are cross-sectional views illustrating an example of the configuration of the semiconductor memory device 1 according to the first embodiment. FIG. 4A is a cross-sectional view illustrating an example of the configuration of the semiconductor memory device 1 according to the first embodiment, and illustrates a peripheral region RP. FIG. 4B is a top view of FIG. 4A viewed from the Z direction. FIG. 4C is an XY plan view of the A-A′ position when viewed in the direction of the arrow in the Z direction. FIG. 4D is an XY plan view of the B-B′ position when viewed in the direction of the arrow in the Z direction.

The memory layer 200 and the first CMOS layer 300 are bonded by a bonding pad 25 and a bonding pad 35 described below contacting each other. In addition, the bonding surface between the memory layer 200 and the first CMOS layer 300 is provided with an oxide film (not illustrated) as well as the bonding pad, and the memory layer 200 and the first CMOS layer 300 may be bonded by the oxide film and the bonding pad.

The first CMOS layer 300 and the second CMOS layer 400 include oxide films 39 and 49 described below on the bonding surface, respectively. The first CMOS layer 300 and the second CMOS layer 400 may be bonded by contacting the oxide films 39 and 49. In the peripheral region RP described below, the first CMOS layer 300 and the second CMOS layer 400 may be bonded by contacting a second via contact electrode CP2 described below and a bonding pad 45 described below in the second CMOS layer 400.

The semiconductor memory device 1 includes an insulating film 20, wiring layers 21 to 24, a bonding pad 25, a conductive layer 26, a diffusion prevention layer 27, an interlayer insulating film 28, a first substrate 30, wiring layers 31 to 33, a bonding pad 35, a diffusion prevention layer 37, the interlayer insulating film 38, an oxide film 39, the second substrate 40, wiring layers 41 to 43, the bonding pad 45, an interlayer insulating film 48, an oxide film 49, the first via contact electrode CP1, the second via contact electrode CP2, a third via contact electrode CP3, transistors TR1 to TR2, and external pads PD1 to PD2.

The semiconductor memory device 1 also includes a memory region RM and the peripheral region RP. The memory region RM is a region including a memory cell array 3. The peripheral region RP is disposed around the memory region RM, and the external pads PD1 to PD2 and the via contact electrodes CP1 to CP3 for supplying the voltage supplied from the external pads PD1 to PD2 to the CMOS circuit are disposed.

The memory layer 200 includes external pads PD1 to PD2, the insulating film 20, wiring layers 21 to 24, the bonding pad 25, the diffusion prevention layer 27, the conductive layer 26, the interlayer insulating film 28, the memory pillar MP, the first via contact electrode CP1, the second via contact electrode CP2, and the third via contact electrode CP3. The memory region RM in the memory layer 200 is included, for example, in a first region. The peripheral region RP in the memory layer 200 is included, for example, in a second region.

The external pads PD1 to PD2 are provided in a plurality of peripheral regions RP in the memory layer 200. Hereinafter, the external pads PD1 to PD2 may be described as the external pad PD.

The external pad PD is electrically connected to the first via contact electrode CP1, and the second via contact electrode CP2, or the third via contact electrode CP3, which will be described below. The external pad PD supplies a voltage to the CMOS circuit formed in the first CMOS layer 300 and the second CMOS layer 400.

The insulating film 20 is formed to surround the wiring layer 21 described below to prevent the external pad PD from being electrically connected to the wiring layer 21. The insulating film 20 includes, for example, silicon oxide (SiO₂).

The first via contact electrode CP1 is formed in the peripheral region RP in the memory layer 200. The first via contact electrode CP1 is electrically connected to the external pad PD1, and is also electrically connected to the second via contact electrode CP2 described below. The first via contact electrode CP1 and the second via contact electrode CP2 supply a voltage from the external pad PD1 to the second CMOS layer 400. The plurality of first via contact electrodes CP1 may also be connected to one external pad PD1. When the plurality of first via contact electrodes CP1 is connected to the one external pad PD1, the plurality of first via contact electrodes CP1 are connected to the one second via contact electrode CP2.

The first via contact electrode CP1 has a height of at least half or more of the height in the Z direction in a first stacked body 29A described below. More specifically, the first via contact electrode CP1 has a height substantially the same as the height in the Z direction in the first stacked body 29A.

The first via contact electrode CP1 includes a conductor, for example, tungsten (W).

The second via contact electrode CP2 is formed in the peripheral region RP in the memory layer 200. The second via contact electrode CP2 is electrically connected to the first via contact electrode CP1 through the conductive layer 26, and is electrically connected to the external pad PD1 through the first via contact electrode CP1.

At the second via contact electrode CP2, the diameter of the surface facing the first via contact electrode CP1 is greater than the diameter of the surface facing the second via contact electrode CP2 at the first via contact electrode CP1. At this time, by connecting the second via contact electrode CP2 to the first via contact electrode CP1 through the conductive layer 26, it is possible to simultaneously connect the plurality of first via contact electrodes CP1 connected to the conductive layer 26 with respect to the one second via contact electrode CP2.

The second via contact electrode CP2 may be connected to the first via contact electrode CP1 through the conductive layer 26, or may be in direct contact with the first via contact electrode CP1 without the conductive layer 26.

The second via contact electrode CP2 contacts the bonding pad 45 of the second CMOS layer 400 described below on a surface opposite to the surface that contacts the conductive layer 26. That is, the second via contact electrode CP2 has a structure that penetrates the first CMOS layer 300 and a part of the memory layer 200, which will described below, in the Z direction. Accordingly, the second via contact electrode CP2 has a height of at least half or more of the height in the Z direction of a second stacked body 29B described below. More specifically, the second via contact electrode CP2 has a height that is almost the same as the height from the second stacked body 29B to the bonding surfaces of the first CMOS layer 300 and the second CMOS layer 400 in the Z direction. That is, the height of the second via contact electrode CP2 is greater than the sum of the height of the second stacked body 29B and the height of the first CMOS layer 300 in the Z direction.

The second via contact electrode CP2 includes a conductor and includes a material different from the first via contact electrode CP1. The second via contact electrode CP2 may contain, for example, copper (Cu) or nickel platinum (NiPt). In addition, the second via contact electrode CP2 may contain a material having a lower resistivity than, for example, tungsten. Hereinafter, the case where the second via contact electrode CP2 contains copper will be described.

A plurality of third via contact electrodes CP3 is disposed in the memory layer 200. A part of the third via contact electrode CP3 is disposed in the memory region RM, and the wiring layer 22 described below is electrically connected to the wiring layer 23 described below through the third via contact electrode CP3.

In addition, a part of the third via contact electrode CP3 is disposed in the peripheral region RP, and is electrically connected to the external pad PD2. At this time, a plurality of third via contact electrodes CP3 may be electrically connected to one external pad PD2. The third via contact electrode CP3 disposed in the peripheral region RP electrically connects the external pad PD2 and the first CMOS layer 300 described below, for example, through the wiring layer 23, the wiring layer 24, and the bonding pad 25, which will be described below. That is, a voltage is supplied from the external pad PD2 to the first CMOS layer 300 through the third via contact electrode CP3. In other words, the third via contact electrode CP3 of the peripheral region RP can supply a voltage to the CMOS layer in direct contact with the layer including the memory cell array.

The height in the Z direction of the third via contact electrode CP3 disposed in the peripheral region RP is greater than the height in the Z direction of the first via contact electrode CP1.

The third via contact electrode CP3 contains, for example, tungsten.

The conductive layer 26 is formed between the first via contact electrode CP1 and the second via contact electrode CP2. In other words, the conductive layer 26 is electrically connected to the first via contact electrode CP1 in a certain surface, and is electrically connected to the second via contact electrode CP2 on a surface opposite to the surface electrically connected to the first via contact electrode CP1.

The size of the surface of the conductive layer 26 in the XY plane is equal to or greater than the size of the surface of the second via contact electrode CP2 facing the first via contact electrode CP1. More specifically, the conductive layer 26 may be circular or quadrilateral in the XY plane, and the diameter of the surface of the conductive layer 26 in the XY plane, or the distance between the opposing sides, is greater than the size of the surface of the second via contact electrode CP2 facing the first via contact electrode CP1. Also, the diameter of the surface of the conductive layer 26 in the XY plane, or the distance between the opposing sides, is smaller than the inner size of the diffusion prevention layer 27 described below.

The conductive layer 26 includes, for example, polysilicon (Poly-Si), or tungsten.

The diffusion prevention layer 27 is provided around the first via contact electrode CP1 and the second via contact electrode CP2. The diffusion prevention layer 27 may be provided at almost the same height from the boundary of the wiring layer 21 and the interlayer insulating film 28 described below in the Z direction to the height of the wiring layer 22 provided at the bottom in the Z direction in the wiring layer 22. Also, the diffusion prevention layer 27 is cylindrical and has a shape that surrounds the inside. Accordingly, the inside of the diffusion prevention layer 27 is shaped such that it is filled with the interlayer insulating film 28. As illustrated in FIG. 4C, the diffusion prevention layer 27 is provided in a circular or quadrilateral shape in the XY plane, for example. That is, the diffusion prevention layer 27 may be provided in a quadrilateral shape having an opening in the XY plane. The diffusion prevention layer 27 is formed to minimize gaps or chips as much as possible that connect the inside of the diffusion prevention layer 27 to the outside of the diffusion prevention layer 27 in the XY plane. This can prevent the diffusion of metals such as copper contained in the second via contact electrode CP2 from the peripheral region RP to other regions. In other words, the height of the diffusion prevention layer 27 in the Z direction may be almost the same as the sum of the height of the first stacked body 29A in the Z direction and the height of the second stacked body 29B in the Z direction described below. The diffusion prevention layer 27 is formed in a shape that surrounds the second via contact electrode CP2, which can prevent the diffusion of metals such as copper into the wiring layer 21 and the wiring layer 22 of the memory region RM. It should be noted that the diffusion prevention layer 27 in the memory layer 200 can also be omitted.

The diffusion prevention layer 27 contains, for example, tungsten.

As illustrated in FIG. 3B, the diffusion prevention layer 27 may be provided to contact the bonding pad 25. In this case, the diffusion prevention layer 27 is connected to the wiring layer 23 and the bonding pad 25 through the wiring layer 24 in the peripheral region RP.

The wiring layer 21 is electrically connected to the memory pillar MP described below. The wiring layer 21 functions as part of the source line. The wiring layer 21 may include, for example, a semiconductor layer such as silicon (Si) into which an N-type impurity such as phosphorus (P) or a P-type impurity such as boron (B) has been injected. Alternatively, the wiring layer 21 may contain a metal such as tungsten, or may contain a silicide such as tungsten silicide (WSi). In addition, an interlayer insulating film 28 described below is formed between the wiring layer 21 and the adjacent wiring layer 22 adjacent to the wiring layer 21.

The wiring layer 22 is formed in a position overlapping a part of the first via contact electrode CP1 and the second via contact electrode CP2 when viewed from the X direction. In addition, a plurality of wiring layers 22 are spaced from each other, and the interlayer insulating film 28 described below is formed between adjacent wiring layers 22. In the memory region RM, a structure which is formed downward in the Z direction of the wiring layer 21 and in which a plurality of insulating layers and a plurality of wiring layers 22 are alternately stacked from the interlayer insulating film 28 contacting the wiring layer 21 is the first stacked body 29A. Further, in the Z direction, a structure which is formed below the first stacked body 29A and in which a plurality of insulating layers and a plurality of wiring layers 22 are alternately stacked is the second stacked body 29B. The first stacked body 29A and the second stacked body 29B may have the same height in the Z direction, or may have different heights. The wiring layer 22 is included, for example, in the first conductive layer or the second conductive layer.

The wiring layer 22 includes a plurality of word lines and a plurality of select gate lines as a plurality of electrode layers in the memory cell array 3. In other words, the wiring layer 22 is formed in the memory region RM in the memory layer 200. The wiring layer 22 has a stair structure, and each wiring layer 22 is electrically connected to the wiring layer 23 through the third via contact electrode CP3. In addition, each memory pillar MP penetrating the plurality of wiring layers 22 is electrically connected to the wiring layer 21 (source line) and the wiring layer 23. A part of the plurality of wiring layers 23 is, for example, a bit line, and the bit line is electrically connected to the memory pillar MP.

The memory pillar MP is provided to penetrate the wiring layer 22 in the memory region RM in the memory layer 200. The memory pillar MP is cylindrical and includes a cylindrical channel film CHL. In the memory pillar MP, a memory film MRL is formed around the channel film CHL. That is, the outer wall of the cylindrical channel film CHL includes a shape such that the memory film MRL surrounds the channel film. The memory film MRL is in contact with the wiring layer 21, the wiring layer 22, and the interlayer insulating film 28 described below. The channel film CHL may include a cylindrical core film containing silicon oxide (SiO₂) and a channel film formed to surround the cylindrical core film. The memory film MRL may include a configuration in which a tunnel insulating film, a charge storage film, and a block insulating film, which are films in contact with the channel film CHL, are staked.

The plurality of wiring layers 23 to 24 is formed in the memory region RM and the peripheral region RP in the memory layer 200.

A part of the wiring layer 23 formed in the memory region RM is electrically connected to the memory pillar MP and functions as a bit line. The other wiring layer 23, that is, the wiring layer 23 formed throughout the memory layer 200, electrically connects the third via contact electrode CP3 described below with the bonding pad of the bonding pad 25 described below. The plurality of wiring layers 23 may include, for example, a barrier conductive film such as titanium nitride (TiN) and a stacked film of a metal film such as copper.

A plurality of wiring layers 24 is provided and electrically connects the wiring layer 23 and the bonding pad 25 described below. The wiring layer 24 may include, for example, a barrier conductive film such as titanium nitride and a stacked film of a metal film such as tungsten.

The plurality of pieces of wiring included in the bonding pad 25 is electrically connected, for example, to at least one of the configuration in the memory layer 200 and the configuration in the first CMOS layer 300. The bonding pad 25 includes a plurality of bonding pads. The plurality of bonding pads 25 may include, for example, a barrier conductive film such as titanium nitride (TiN) and a stacked film of a metal film such as copper. It should be noted that hereinafter, one bonding pad included in the memory layer 200 may be described as the bonding pad 25, or a plurality of bonding pads included in the memory layer 200 may be described as the bonding pad 25.

The interlayer insulating film 28 fills the memory layer 200 and insulates other elements from each other. A part of the interlayer insulating film 28 is formed between the wiring layer 21 and the plurality of wiring layers 22 to prevent the adjacent wiring layer 21, the wiring layer 22, and the adjacent wiring layer 22 from being electrically connected to each other. The interlayer insulating film 28 formed between the wiring layer 21 and the wiring layer 22 is layered and functions as an insulating layer.

The interlayer insulating film 28 is, for example, a silicon oxide film or a silicon nitride film. The interlayer insulating film 28 is, for example, a silicon oxide film, or a stacked film including the silicon oxide film and the other insulating film.

The first CMOS layer 300 includes the first substrate 30, wiring layers 31 to 33, a bonding pad 35, a diffusion prevention layer 37, an interlayer insulating film 38, an oxide film 39, and a transistor TR1. The first CMOS layer 300 includes a first CMOS circuit.

The first substrate 30 is a silicon wafer and includes, for example, a P-type silicon containing a P-type impurity such as boron. The surface of the first substrate 30 is provided with, for example, an N-type well region containing an N-type impurity such as phosphorus, a P-type well region containing a P-type impurity such as boron, and a semiconductor substrate region without an N-type well region and a P-type well region, and an insulating region. The N-type well region and the P-type well region each function as a part of a plurality of transistors, a plurality of capacitors, or the like that constitute the CMOS circuit.

The wiring layers 31 to 33 are provided in the interlayer insulating film 38 described below, and in order from the first substrate 30 side, the wiring layer 31, the wiring layer 32, and the wiring layer 33 are formed. The wiring layers 31 to 33 are provided with wiring of the first CMOS layer 300.

In the semiconductor memory device 1, the wiring layers 31 to 33 provided in the memory region RM are electrically connected to the wiring layers 23 and 24 and the like of the memory layer 200 through the bonding pads 25 and 35.

The plurality of wiring layers 31 to 33 may include, for example, a barrier conductive film such as titanium nitride and a stacked film of a metal film such as tungsten. Alternatively, the plurality of wiring layers 31 to 33 may include, for example, a barrier conductive film such as titanium nitride, a stacked film of tantalum nitride (TaN) and tantalum (Ta), and a metal film such as copper.

The plurality of pieces of wiring included in the bonding pad 35 is electrically connected, for example, to at least one of the configuration in the first CMOS layer 300 and the configuration in the memory layer 200. The bonding pad 35 includes a plurality of bonding pads. The plurality of bonding pads 35 may include, for example, a barrier conductive film such as titanium nitride and a stacked film of a metal film such as copper. It should be noted that hereinafter, one bonding pad included in the first CMOS layer 300 may be described as the bonding pad 35, or a plurality of bonding pads included in the first CMOS layer 300 may be described as the bonding pad 35.

The bonding pad included in the bonding pad 35 bonds the memory layer 200 and the first CMOS layer 300 by contacting the bonding pad in the bonding pad 25 at the bonding surface of the memory layer 200 and the first CMOS layer.

The diffusion prevention layer 37 is provided around the second via contact electrode CP2. The one end of the diffusion prevention layer 37 is in contact with the bonding pad 35 in the Z direction, for example. The end opposite to the end contacting the bonding pad 35 is at least in contact with the first substrate 30, and may penetrate the first substrate 30.

The shape of the diffusion prevention layer 37 may be the same as the diffusion prevention layer 27. Also, as illustrated in FIG. 4D, in the XY plane, the size of the opening of the diffusion prevention layer 37 is greater than the surface that penetrates the first substrate 30 of the second via contact electrode CP2.

The diffusion prevention layer 37 is also formed to minimize gaps as much as possible that connect the inside of the diffusion prevention layer 27 to the outside of the diffusion prevention layer 27 in the XY plane as well as the diffusion prevention layer 27. This can prevent the diffusion of metals such as copper contained in the second via contact electrode CP2 from the peripheral region RP to other regions. In other words, the diffusion prevention layer 37 is formed in a shape that surrounds the second via contact electrode CP2, which can prevent the diffusion of metals such as copper into the wiring layers 31 to 33 and the transistor TR1.

The diffusion prevention layer 37 includes, for example, tungsten.

The interlayer insulating film 38 is provided on the first substrate 30. The interlayer insulating film 38 covers the circuits (for example, the wiring layers 31 to 33) provided on the first substrate 30. The interlayer insulating film 38 may include a plurality of insulating layers.

The oxide film 39 is provided below the first substrate 30 in the Z direction and is in contact with the oxide film 49 included in the second CMOS layer 400 described below. By contacting the oxide film 39 and the oxide film 49 described below, the first CMOS layer 300 and the second CMOS layer 400 are bonded. In other words, the boundary between the oxide film 39 and the oxide film 49 described below corresponds to a bonding surface between the first CMOS layer 300 and the second CMOS layer 400.

The oxide film 39 contains, for example, silicon oxide.

The transistor TR1 includes a MOSFET structure including a gate electrode, a source/drain region, and the like. The source/drain region of the MOSFET is electrically connected to the bonding pad formed in the bonding pad 35 by the wiring layers 31 to 33.

The second CMOS layer 400 includes the second substrate 40, wiring layers 41 to 43, the bonding pad 45, an interlayer insulating film 48, the oxide film 49, and a transistor TR2. The second CMOS layer 400 includes a second CMOS circuit.

The second CMOS layer 400 may include a CMOS circuit that performs a high-speed operation, for example. If a CMOS circuit that performs high-speed operation is included, an efficient voltage supply can be performed by reducing the resistivity of the voltage supply from the external pad PD.

The second substrate 40 is a silicon wafer and includes, for example, a P-type silicon containing a P-type impurity such as boron. The configuration of the second substrate 40 is the same as that of the first substrate 30, and thus the descriptions thereof will be omitted.

The wiring layers 41 to 43 are provided in the interlayer insulating film 48 described below, and in order from the second substrate 40 side, the wiring layer 41, the wiring layer 42, and the wiring layer 43 are formed. The wiring layers 41 to 43 are provided with the wiring of the second CMOS layer 400 and are electrically connected to each other.

The materials included in the plurality of wiring layers 41 to 43 are similar to the wiring layers 31 to 33, and thus the descriptions thereof will be omitted.

The bonding pad 45 is electrically connected to the external pad PD1 through the first via contact electrode CP1 and the second via contact electrode CP2. The bonding pad included in the bonding pad 45 may be electrically connected to the wiring layer 43 through a plurality of via plugs. The bonding pad 45 may include, for example, a barrier conductive film such as titanium nitride and a stacked film of a metal film such as copper. It should be noted that hereinafter, one bonding pad included in the second CMOS layer 400 may be described as the bonding pad 45, or a plurality of bonding pads included in the second CMOS layer 400 may be described as the bonding pad 45.

The bonding pad 45 is bonded to the first CMOS layer 300 and the second CMOS layer 400 by contacting the second via contact electrode CP2 at the bonding surface of the first CMOS layer 300 and the second CMOS layer 400. The bonding pad 45 is embedded in the oxide film 49 and the surface thereof is exposed from the oxide film 49.

The plane (XY plane) of the oxide film 49 side in the bonding pad 45 is greater than or equal to the diameter of the plane (XY plane) of the oxide film 39 side in the second via contact electrode CP2, for example.

The interlayer insulating film 48 is provided on the second substrate 40. The interlayer insulating film 48 is similar to the interlayer insulating film 38, and thus the descriptions thereof will be omitted.

The oxide film 49 is provided above the second substrate 40 in the Z direction and is in contact with the oxide film 39.

The oxide film 49 contains, for example, silicon oxide.

The transistor TR2 includes a MOSFET structure including a gate electrode, a source/drain region, and the like. The source/drain region of the MOSFET is electrically connected to the bonding pad 45 by the wiring layers 41 to 43.

FIGS. 5 to 15 are cross-sectional views illustrating an example of a cross-sectional structure during manufacturing of the memory layer 200 according to the first embodiment.

As illustrated in FIG. 5, in the memory region RM of the semiconductor memory device 1, the sacrifice layer 22′is stacked in a stepped manner on the wiring layer 21. The substrate (not illustrated) may be provided under the wiring layer 21. The sacrifice layer 22′ is a layer that is replaced by the wiring layer 22 in a later step, and includes silicon nitride, for example. At this time, the wiring layer 21 and the sacrifice layer 22′, and the plurality of sacrifice layers 22′ are spaced from each other in the Z direction, and an interlayer insulating film 28 is formed therebetween. In addition, due to the formation of the interlayer insulating film 28, the peripheral region RP in the Z direction is also aligned at almost the same height as the memory region RM. The stacked body formed by the sacrifice layer 22′ formed in FIG. 5 and the interlayer insulating film 28 formed between the sacrifice layers 22′ is the first stacked body 29A. The sacrifice layer 22′ formed at this time is included, for example, in a first sacrifice layer. At this time, the interlayer insulating film 28 formed between the wiring layer 21 and the sacrifice layer 22′and the interlayer insulating film 28 formed between the plurality of sacrifice layers 22′ are included in the first insulating layer. The interlayer insulating film 28 formed in the peripheral region RP is included, for example, in the first insulator.

As illustrated in FIG. 6, in the memory region RM, a plurality of memory holes MH penetrating the first stacked body 29A are formed. The memory hole MH is formed by anisotropic etching, for example. At this time, a plurality of first via contact holes CP1′ is also formed in the peripheral region RP. That is, the height in the Z direction of the first via contact electrode CP1 is almost the same as the height of the memory hole MH.

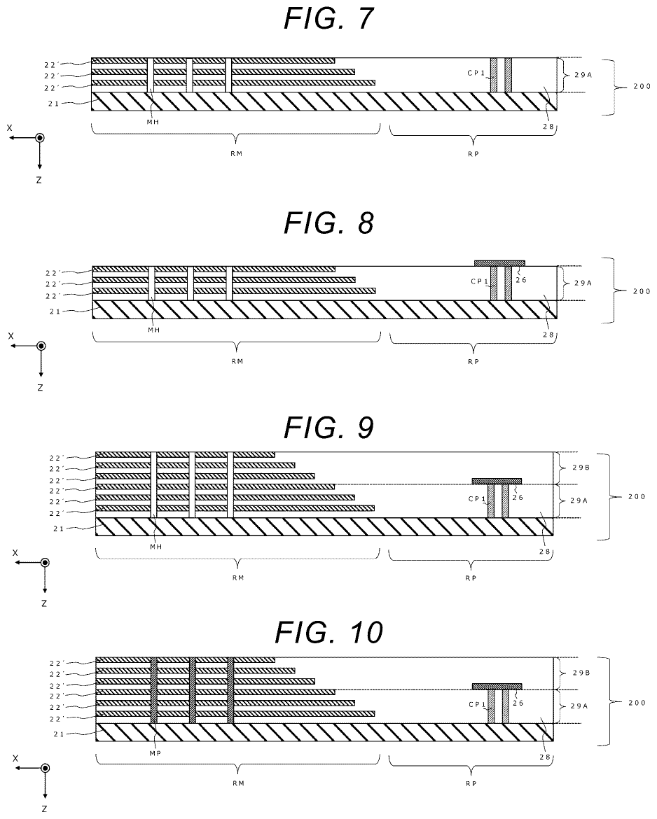

As illustrated in FIG. 7, tungsten or the like is embedded in the first via contact hole CP1′ in the peripheral region RP to form the first via contact electrode CP1.

As illustrated in FIG. 8, in the peripheral region RP, the conductive layer 26 is formed on the first via contact electrode CP1. The conductive layer 26 is deposited, for example, across the surface of the memory layer 200, that is, across the surface to which the first via contact electrode CP1 is exposed. It may then be etched by the RIE (Reactive Ion Etching) method and formed on the first via contact electrode CP1 of the peripheral region RP.

As illustrated in FIG. 9, in the memory region RM of the semiconductor memory device 1, the sacrifice layer 22′ is stacked in a stepped manner on the first stacked body 29A. Further, when viewed from the Z direction, a hole penetrating the second stacked body 29B is formed to overlap with the memory hole MH formed in the first stacked body 29A, and the height of the memory hole MH in the Z direction is greater than the height of the memory hole MH in the step of FIG. 5. The stacking method of the sacrifice layer 22′ may be the same as the step of FIG. 5. At this time, the plurality of sacrifice layers 22′ are spaced from each other in the Z direction, and the interlayer insulating film 28 is formed therebetween. Due to the formation of the interlayer insulating film 28, the peripheral region RP in the Z direction is also aligned at almost the same height as the memory region RM. The stacked body formed by the sacrifice layer 22′ formed in FIG. 9 and the insulating layer formed between the sacrifice layers 22′ is the second stacked body 29B. The sacrifice layer 22′ formed in the memory region RM in FIG. 9 is included, for example, in the second sacrifice layer. In addition, the interlayer insulating film 28 formed between the plurality of sacrifice layers 22′ in FIG. 9 is included in the second insulating layer. The interlayer insulating film 28 formed in the peripheral region RP is included, for example, in the second insulator.

As illustrated in FIG. 10, the memory pillar MP is formed by embedding a plurality of films inside the memory hole MH. The memory pillar MP includes, for example, a block insulating film, an electrochemical storage film, a tunnel insulating film, a channel film, and a core film from the side in contact with the sacrifice layer 22′ and the interlayer insulating film 28 to the inward.

As illustrated in FIG. 11, in the peripheral region RP, the first via contact electrode CP1 and the slit 27′ are formed to surround the conductive layer 26. The slit 27′ is the diffusion prevention layer 27 before embedding the material. The slit 27′ may be in a shape that surrounds the first via contact electrode CP1, the conductive layer 26, and the second via contact electrode CP2 formed in the subsequent step when viewed from the Z direction, for example, in a quadrilateral shape or a circular shape. Further, the height in the Z direction of the slit 27′ is almost equal to the height in the Z direction of the stacked body including the first stacked body 29A and the second stacked body 29B. In this case, the slit 27′ is formed in the peripheral region RP when a slit (not illustrated) is formed in the memory region RM.

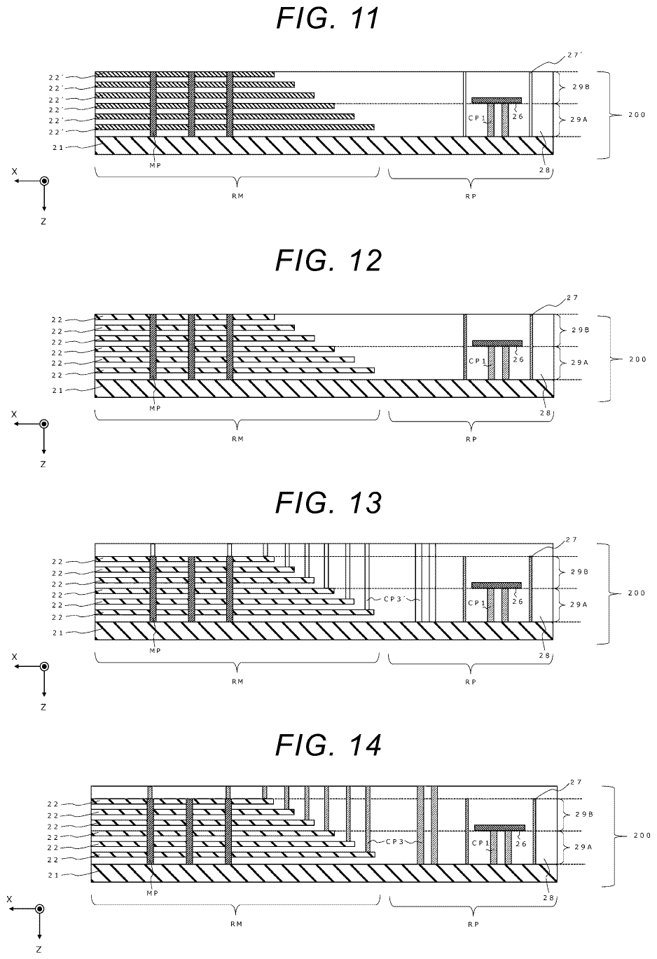

It should be noted that the slit 27′ may be formed in the peripheral region RP when forming the third via contact hole CP3′, which will be described below. When the slit 27′ is also formed at the timing of forming the third via contact hole CP3′ described below, the height in the Z direction of the slit 27′ is almost the same as the height of the third via contact hole CP3′ in the peripheral region RP. In other words, the slit 27′ can be formed other than at the timing as in FIG. 12, and the height in the Z direction of the slit 27′ formed during the formation step of the third via contact hole CP3′ is greater than the height in the Z direction of the slit 27′ in FIG. 11.

As illustrated in FIG. 12, in the memory region RM, the sacrifice layer 22′ is removed and replaced by the wiring layer 22. In addition, tungsten is embedded in the slit 27′ formed in the peripheral region RP, resulting in the diffusion prevention layer 27.

As illustrated in FIG. 13, an insulating film is formed across the surface of the memory layer 200 to form the third via contact hole CP3′ in the memory region RM and the peripheral region RP. A hole is also formed on the memory pillar MP to form a via plug that is electrically connected to the memory pillar MP. The insulating film formed on the memory layer 200 formed in FIG. 13 is included in the interlayer insulating film 28. It should be noted that as described above, when forming the third via contact hole CP3′ in FIG. 13, the slit 27′ may be formed in the peripheral region RP.

As illustrated in FIG. 14, a material containing tungsten is embedded in the hole on the third via contact hole CP3′ and the memory pillar MP to form the third via contact electrode CP3 and the via plug.

As illustrated in FIG. 15, an insulating film, the wiring layers 23 to 24, a via plug, and the bonding pad 25 are formed on the interlayer insulating film 28. The insulating film further formed in FIG. 15 is included in the interlayer insulating film 28. In this manner, the wiring layers 23 to 24, the via plug, and the bonding pad 25 are formed, and the memory layer 200 can be electrically connected to the first CMOS layer 300 described below.

When forming the diffusion prevention layer 27 as in FIG. 3B, the diffusion prevention layer 27 is formed in the same manner as the third via contact electrode CP3 in the peripheral region RP. That is, the diffusion prevention layer 27 may also be formed at the timing when the third via contact electrode CP3 in the peripheral region RP is formed in FIGS. 13 to 15. In this case, the diffusion prevention layer 27 is formed to contact the bonding pad 25 through the wiring layers 23 and 24.

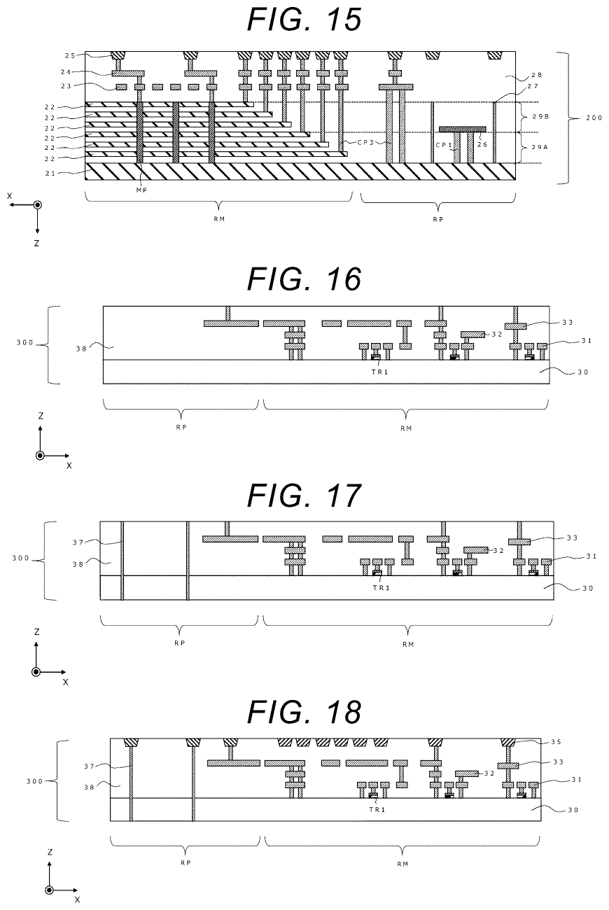

FIGS. 16 to 18 are cross-sectional views illustrating an example of a cross-sectional structure during manufacturing of the first CMOS layer 300 according to the first embodiment.

As illustrated in FIG. 16, a via plug connecting the transistor TR1, the wiring layers 31 to 33, the interlayer insulating film 38, and the wiring layers 31 to 33 is formed on the first substrate 30.

As illustrated in FIG. 17, in the peripheral region RP, the interlayer insulating film 38 and the diffusion prevention layer 37 that penetrates the first substrate 30 are formed. The diffusion prevention layer 37 may be in a shape that surrounds the second via contact electrode CP2 formed in the subsequent step when viewed from the Z direction, for example, in a quadrilateral shape or a circular shape.

As illustrated in FIG. 18, the bonding pad 35 is formed on the first CMOS layer 300. The bonding pad 35 is in contact with the via plug or the diffusion prevention layer 37. By electrically connecting the wiring layers 31 to 33 to the bonding pad 35, the first CMOS layer 300 electrically connects to the memory layer 200 and the external pad PD described below.

FIGS. 19 to 22 are cross-sectional views illustrating an example of the bonding process of the memory layer 200 and the first CMOS layer 300 according to the first embodiment.

As illustrated in FIG. 19, the memory layer 200 and the first CMOS layer 300 are arranged so as to face each other. In other words, the memory layer 200 and the first CMOS layer 300 are arranged such that the bonding pad 25 formed in the memory layer 200 and the bonding pad 35 formed in the first CMOS layer 300 face each other.

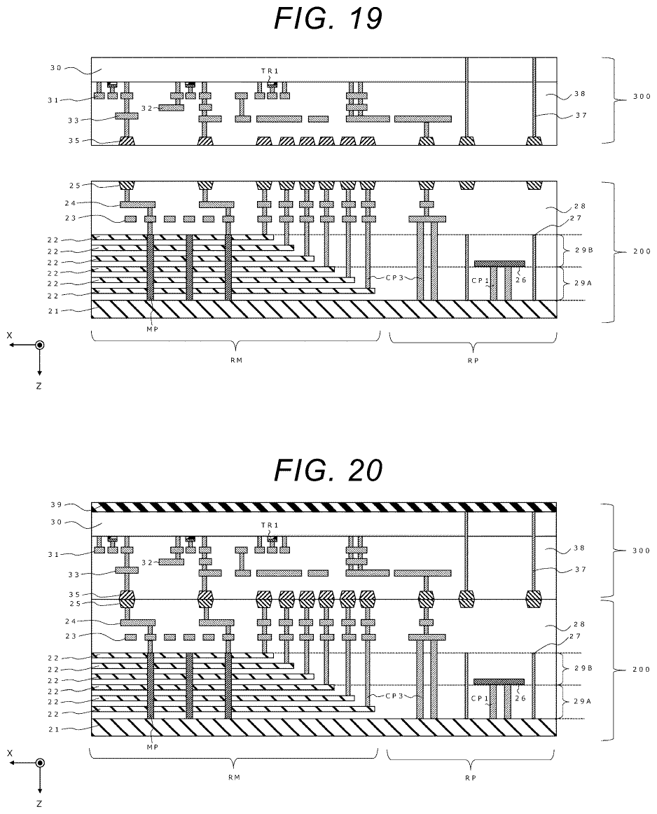

As illustrated in FIG. 20, the bonding process is performed, and the memory layer 200 and the first CMOS layer 300 are bonded. In addition, the oxide film 39 is formed on the surface opposite to the bonding surface of the memory layer 200 of the first CMOS layer. The bonding pad 25 and the bonding pad 35 correspond, and the bonding pad 25 and the bonding pad 35 are electrically connected. This causes the memory layer 200 and the first CMOS layer 300 to be electrically connected.

As illustrated in FIG. 21, the second via contact hole CP2′ is formed in the memory layer 200 after the bonding process and the peripheral region RP of the first CMOS layer 300. The second via contact hole CP2′ is the second via contact electrode CP2 before the material containing copper is embedded. The second via contact hole CP2′ is formed from the oxide film 39 side of the first CMOS layer 300, penetrates the first CMOS layer 300, and is formed up to the conductive layer 26 of the memory layer 200. In other words, the second via contact hole CP2′ is formed by anisotropic etching to penetrate a part of the oxide film 39, the first substrate 30, the interlayer insulating film 38, and the interlayer insulating film 28 to reach the conductive layer 26. The conductive layer 26 has a low etching rate compared to the interlayer insulating film 28, and is less likely to be anisotropically etched. As such, the conductive layer 26 also has a function as an etching stopper layer. Thus, the anisotropic etching to form the second via contact hole CP2′ can be stopped after reaching the conductive layer 26 and before penetrating the conductive layer 26. When viewed from the negative direction of the Z direction, the second via contact hole CP2′ is formed to overlap the conductive layer 26 and the first via contact electrode CP1. In other words, when viewed from the negative direction of the Z direction, the conductive layer 26 is exposed.

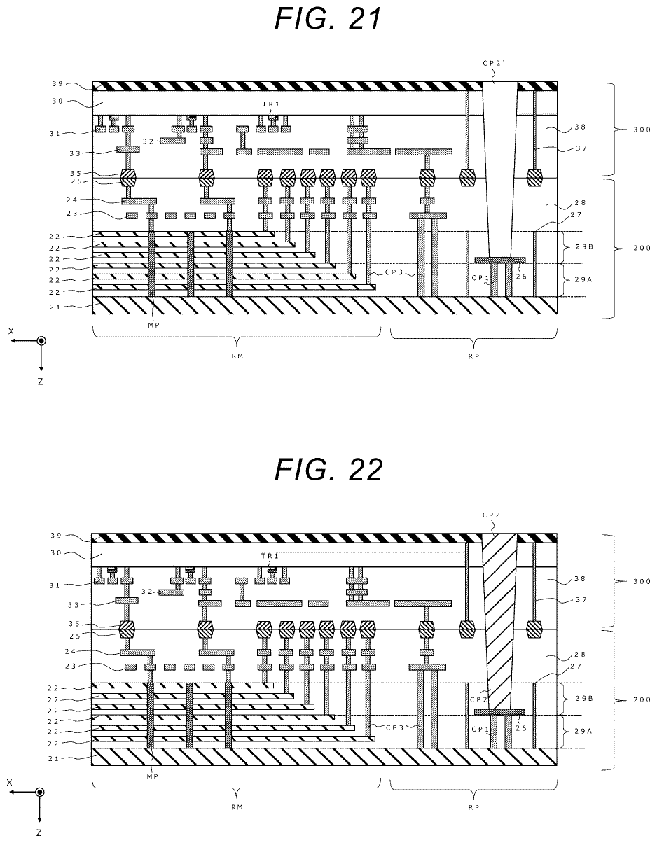

As illustrated in FIG. 22, a material containing copper is embedded in the second via contact hole CP2′ to form the second via contact electrode CP2. The second via contact electrode CP2 is formed from the oxide film 39 side of the first CMOS layer 300, penetrates the first CMOS layer 300, and is formed up to the conductive layer 26 of the memory layer 200. In other words, the second via contact electrode CP2 is formed to penetrate the oxide film 39, the first substrate 30, the interlayer insulating film 38, and the interlayer insulating film 28 to contact the conductive layer 26.

When embedding a material containing copper in the second via contact hole CP2′, the diffusion prevention layer 27 is provided to surround the second via contact hole CP2′, so that the diffusion of copper can be prevented in the memory layer 200 and other regions in the first CMOS layer 300.

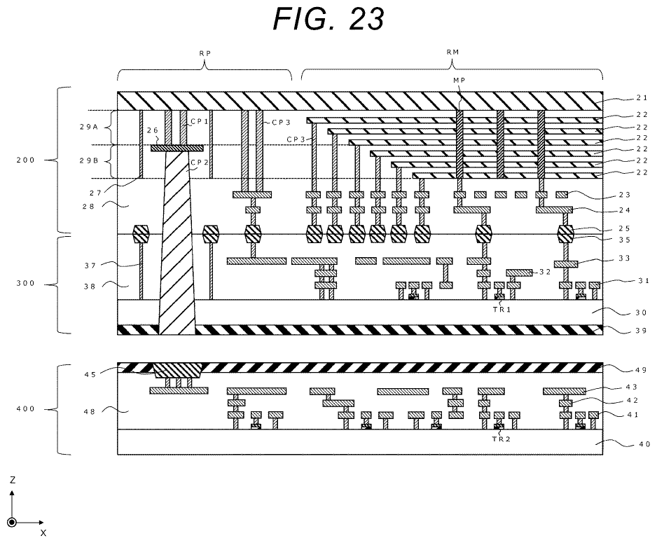

FIGS. 23 to 25 are cross-sectional views illustrating an example of the bonding process of the first CMOS layer 300 and the second CMOS layer 400 according to the first embodiment.

As illustrated in FIG. 23, the first CMOS layer 300 and the second CMOS layer 400 are arranged so as to face each other. In other words, the first CMOS layer 300 and the second CMOS layer 400 are arranged such that the oxide film 39 formed in the first CMOS layer 300 and the second via contact electrode CP2 face each other, and the oxide film 49 formed in the second CMOS layer 400 and the bonding pad 45 face each other.

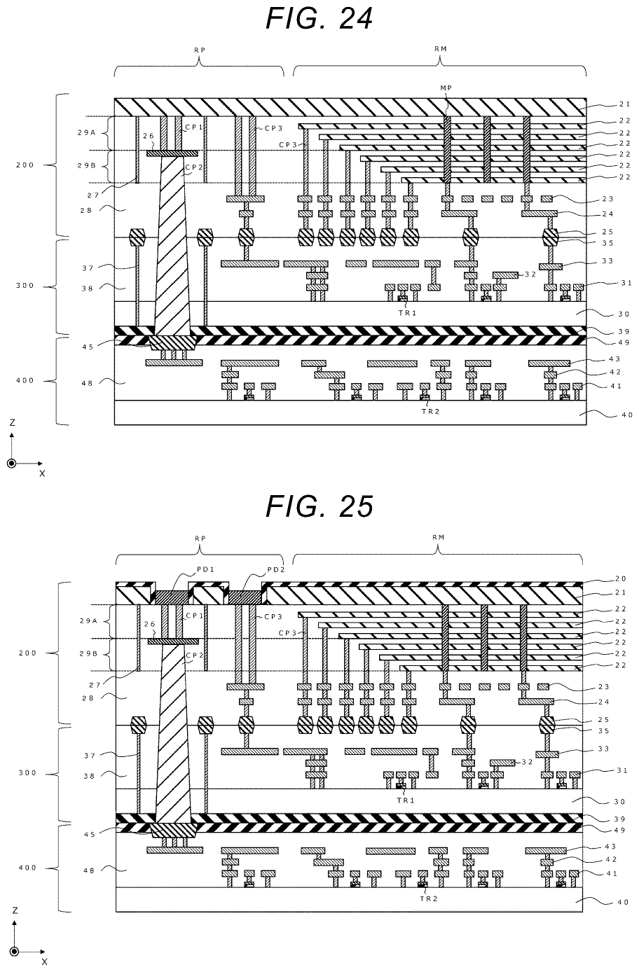

As illustrated in FIG. 24, the bonding process is performed, and the first CMOS layer 300 and the second CMOS layer 400 are bonded. The bonding pad 45 and the second via contact electrode CP2 face each other, and the bonding pad 45 and the second via contact electrode CP2 are electrically connected by the bonding process. Through this, the second CMOS layer 400 and the external pad PD1 described below can be electrically connected. In addition, by contacting the oxide film 39 and the oxide film 49, the memory layer 200 and the first CMOS layer 300 are bonded to the second CMOS layer 400.

As illustrated in FIG. 25, the insulating film 20 and the external pads PD1 and PD2 are formed on the wiring layer 21 of the memory layer 200 by etching the wiring layer 21.

The insulating film 20 is formed to surround the external pads PD1 and PD2 when viewed from the Z direction, and is electrically insulated from the wiring layer 21 and the external pads PD1 and PD2 by the insulating film 20.

The external pads PD1 and PD2 are provided in the peripheral region RP, and are electrically connected to the first via contact electrode CP1 and the third via contact electrode CP3. The second via contact electrode CP2 is also connected to the external pad PD1 through the first via contact electrode CP1. By electrically connecting the external pad PD1 to the first via contact electrode CP1 and the second via contact electrode CP2, a voltage can be supplied from the external pad PD1 to the second CMOS layer 400. Furthermore, the external pad PD2 and the third via contact electrode CP3 are electrically connected, so that a voltage can be supplied from the external pad PD2 to the first CMOS layer 300.

According to the first embodiment, after the bonding process of the memory layer 200 and the first CMOS layer 300, the second via contact electrode CP2 is formed, which penetrates from the surface opposite to the bonding surface of the first CMOS layer 300 to the first CMOS layer 300 and the middle of the memory layer 200. One second via contact electrode CP2 corresponding to the plurality of first via contact electrodes CP1 can also be formed, and the second via contact electrode CP2 having a thicker diameter in the XY plane than the first via contact electrode CP1 can be formed. In addition, by separately forming the first via contact electrode CP1 and the second via contact electrode CP2, a material having a lower resistivity than the first via contact electrode CP1 can be used for the second via contact electrode CP2. In other words, the second via contact hole CP2′ that penetrates the first CMOS layer 300 from the first substrate 30 side and reaches the middle of the memory layer 200 is formed in bulk, and the second via contact electrode CP2 is formed using a material with a lower resistivity than tungsten.

In the present embodiment, by forming the second via contact electrode CP2 as described above, the resistance when supplying a voltage from the external pad PD1 to the second CMOS layer 400 can be reduced. More specifically, when a CMOS circuit for high-speed operation is provided in the second CMOS layer 400, by providing the second via contact electrode CP2 with low resistance, it is possible to efficiently supply a voltage from the external pad PD to the CMOS circuit in the second CMOS layer 400.

Further, in the present embodiment, the first CMOS layer 300 and the external pad PD2 are connected through the third via contact electrode CP3, and the second CMOS layer 400 and the external pad PD1 are connected through the first via contact electrode CP1 and the second via contact electrode CP2. This can reduce the space in the peripheral region RP than connecting the first via contact electrode CP1 and the second via contact electrode CP2 to all the external pads PD. That is, the connection between the first CMOS layer 300 and the external pad PD2 can also reduce the space of the peripheral region RP in the present embodiment compared to the case through the first via contact electrode CP1 and the second via contact electrode CP2.

It should be noted that the connection between the second CMOS layer 400 and the external pad PD1 may be performed not only by the first via contact electrode CP1 and the second via contact electrode CP2, but also through the third via contact electrode CP3.

In the present embodiment, the first stacked body 29A is formed in the memory region RM of the memory layer 200, and the interlayer insulating film 28 is also formed in the peripheral region RP. The conductive layer 26 in the peripheral region RP is then formed on the interlayer insulating film 28 formed at this time. By forming the conductive layer 26 during the stacking of the wiring layer 22, it is possible to prevent the formation of the wiring layer 21, the insulating film 20, the external pad PD, and the like.

In the semiconductor memory device 1, as the wiring layer 22 of the memory layer 200 is further stacked, the aspect ratio of the via contact electrode in the peripheral region RP is also higher. At this time, the stacked layers of the wiring layer 22 in the memory layer 200 may be divided into a plurality of stacked bodies, and the plurality of stacked bodies may be stacked in order. In the present embodiment, the first via contact electrode CP1 is formed at the same timing as the step of forming the stacked body that is first stacked in the memory layer 200. This allows the first via contact electrode CP1 to be formed without the need for an additional process, even if the wiring layer 22 in the memory layer 200 is further stacked. In addition, since the second via contact electrode CP2 can form a larger diameter in the XY plane than the first via contact electrode CP1, even if the wiring layer 22 is highly stacked, it is less affected than the first via contact electrode CP1.

As the wiring layer 22 is highly stacked and the stacked body is increased, the proportion of the second via contact electrode CP2 when electrically connecting the external pad PD and the second CMOS layer 400 increases. Thus, as the wiring layer 22 is highly stacked, the proportion of the second via contact electrode CP2 is relatively large, so the resistance when supplying a voltage from the external pad PD to the second CMOS layer 400 is relatively low.

### Second Embodiment

The configuration of the semiconductor memory device according to a second embodiment is different in the configuration of the memory layer 200.

FIG. 26 is a cross-sectional view illustrating an example of a configuration of the semiconductor memory device 1 according to the second embodiment.

In the semiconductor memory device 1 according to the second embodiment, it is different from the first embodiment in that a third stacked body 29C is formed in the memory region RM of the memory layer 200.

The semiconductor memory device 1 includes an insulating film 20, wiring layers 21 to 24, a bonding pad 25, a conductive layer 26, a diffusion prevention layer 27, an interlayer insulating film 28, a first substrate 30, wiring layers 31 to 33, an interlayer insulating film 38, an oxide film 39, the second substrate 40, wiring layers 41 to 43, an interlayer insulating film 48, an oxide film 49, a first via contact electrode CP1, a second via contact electrode CP2, a third via contact electrode CP3, and transistors TR1 to TR2.

The semiconductor memory device 1 also includes a memory region RM and the peripheral region RP. The memory region RM is a region including a memory cell array 3. The peripheral region RP is disposed around the memory region RM, and the external pad PD and the via contact electrode for supplying the voltage supplied from the external pad PD to the CMOS circuit are disposed.

The memory layer 200 includes external pads PD1 to PD2, the insulating film 20, wiring layers 21 to 24, the bonding pad 25, the conductive layer 26, the diffusion prevention layer 27, the interlayer insulating film 28, the memory pillar MP, the first via contact electrode CP1, the second via contact electrode CP2, and the third via contact electrode CP3.

The external pad PD, the insulating film 20, the wiring layer 21, the wiring layer 23, the bonding pad 25, the conductive layer 26, the interlayer insulating film 28, the third via contact electrode CP3, and the memory pillar MP are similar to the first embodiment, and thus the descriptions thereof will be omitted.

The first via contact electrode CP1 is formed in the peripheral region RP in the memory layer 200. The first via contact electrode CP1 may be similar to the first embodiment and has a height of at least half or more of the height in the Z direction in the first stacked body 29A described below.

The second via contact electrode CP2 is formed in the peripheral region RP in the memory layer 200. The second via contact electrode CP2 may also be the same as the first embodiment, and the diameter of the surface facing the first via contact electrode CP1 at the second via contact electrode CP2 is greater than the diameter of the surface facing the second via contact electrode CP2 at the first via contact electrode CP1.

The second via contact electrode CP2 has a height of at least half or more of the height in the Z direction of the second stacked body 29B described below, as in the first embodiment. More specifically, the second via contact electrode CP2 has a height that is almost the same as the height from the second stacked body 29B to the bonding surfaces of the first CMOS layer 300 and the second CMOS layer 400 in the Z direction. In the second embodiment, the wiring layer 22 described below includes the third stacked body 29C. Accordingly, the height in the Z direction of the second via contact electrode CP2 is higher than in the first embodiment.

The wiring layer 22 is similar to the first embodiment and is formed in a position overlapping a part of the first via contact electrode CP1 and the second via contact electrode CP2 when viewed from the X direction. In addition, a plurality of wiring layers 22 are spaced from each other, and the interlayer insulating film 28 described below is formed between adjacent wiring layers 22. In the memory region RM, a structure which is formed downward in the Z direction of the wiring layer 21 and in which a plurality of insulating layers and a plurality of wiring layers 22 are alternately stacked from the interlayer insulating film 28 contacting the wiring layer 21 is the first stacked body 29A. Further, in the Z direction, a structure which is formed below the first stacked body 29A and in which a plurality of insulating layers and the wiring layer 22 are alternately stacked is the second stacked body 29B. In the second embodiment, in the Z direction, the structure which is formed below the second stacked body 29B and in which the plurality of insulating layers and the wiring layer 22 are alternately stacked is the third stacked body 29C. The first stacked body 29A, the second stacked body 29B, and the third stacked body 29C may have the same height in the Z direction, or may have different heights.

The configuration of the first CMOS layer 300 and the second CMOS layer 400 may be the same as that of the first embodiment, and thus the descriptions thereof will be omitted.

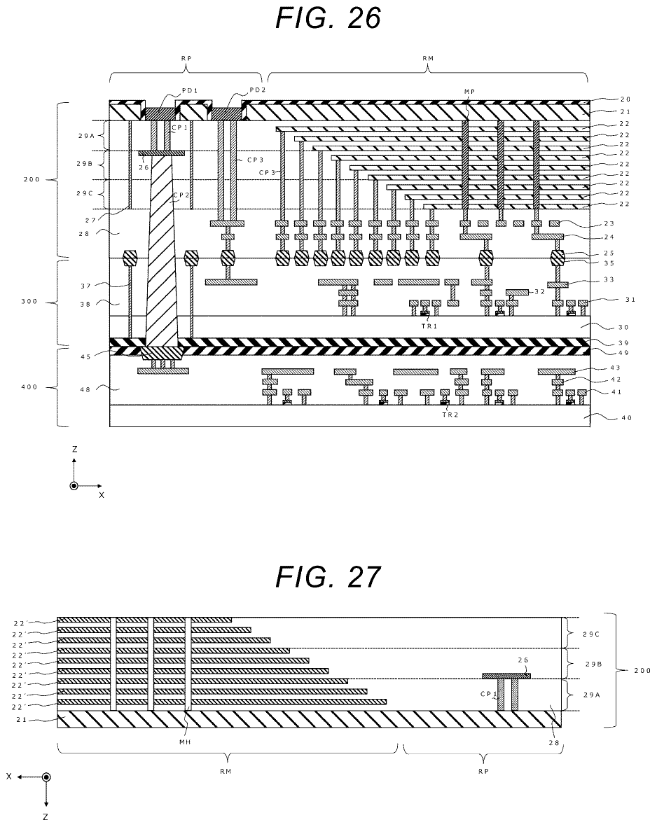

FIG. 27 is a cross-sectional view illustrating an example of a cross-sectional structure during manufacturing of the memory layer 200 according to the second embodiment.

The manufacturing step until the second stacked body 29B illustrated in FIG. 27 is formed is similar to that of FIGS. 5 to 9 of the first embodiment, and thus the descriptions thereof will be omitted. In the second embodiment, the third stacked body 29C is further stacked above the second stacked body 29B.

As illustrated in FIG. 27, in the memory region RM of the semiconductor memory device 1, the sacrifice layer 22′ is stacked in a stepped manner on the second stacked body 29B. The stacked body formed by the sacrifice layer 22′ formed on the second stacked body 29B and the interlayer insulating film 28 formed between the sacrifice layers 22′ is the third stacked body 29C. Further, when viewed from the Z direction, a hole is formed that penetrates the first stacked body 29A, the second stacked body 29B, and the third stacked body 29C. The stacking method of the sacrifice layer 22′ may be the same as that of the first embodiment. At this time, the plurality of sacrifice layers 22′ are spaced from each other in the Z direction, and the interlayer insulating film 28 is formed therebetween. Due to the formation of the interlayer insulating film 28, the height of the peripheral region RP in the Z direction is also aligned at the height of the memory region RM.

Thereafter, the semiconductor memory device 1 of the second embodiment as illustrated in FIG. 26 can be formed by manufacturing in the same step as illustrated in FIGS. 10 to 25.

In such a semiconductor memory device of the second embodiment, the same effect as in the first embodiment can be obtained.

As the wiring layer 22 is highly stacked and the stacked body is increased, the proportion of the second via contact electrode CP2 when electrically connecting the external pad PD and the second CMOS layer 400 increases. Thus, in the present embodiment, since the third stacked body 29C is included in the wiring layer 22, the proportion of the second via contact electrode CP2 is relatively large, and the resistance when supplying a voltage from the external pad PD to the second CMOS layer 400 is relatively low.

### Third Embodiment

The semiconductor memory device of the third embodiment includes a memory cell and a CMOS circuit for accessing the memory cell. Hereinafter, details of the third embodiment will be described.

Since the configuration example of the semiconductor memory device according to the third embodiment is the same as that of the first embodiment, a brief description will be made.

FIG. 28 is a perspective view illustrating an example of the appearance of the semiconductor memory device 1 according to the third embodiment. The semiconductor memory device 1 has a structure in which the memory layer 200 and a third CMOS layer 500 are stacked in order, for example, from top to bottom in the Z direction.

The third embodiment is different from the first embodiment in that one third CMOS layer 500 is provided for one memory layer 200.

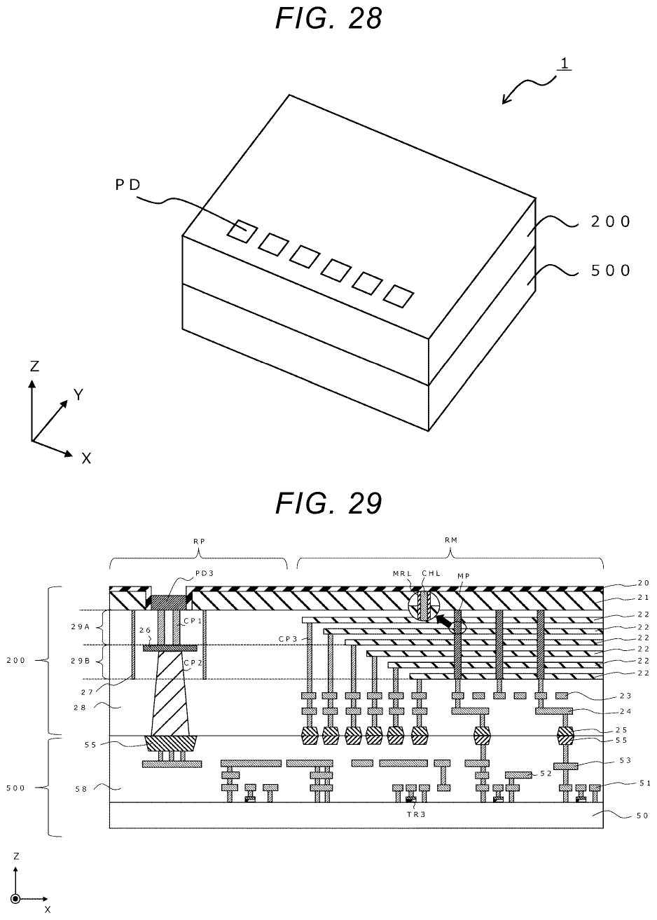

FIG. 29 is a cross-sectional view illustrating an example of a configuration of the semiconductor memory device 1 according to the third embodiment.

In the Z direction, the third CMOS layer 500 may include a third substrate 50 under the CMOS layer. In addition, the memory layer 200 may also have a wiring layer on the memory layer in the Z direction. It should be noted that the wiring layer in the memory layer 200 includes a layer formed on the memory after the bonding process of the memory layer 200 and the third CMOS layer 500 described below. The wiring layer includes, for example, a plurality of external pads PD used to connect the semiconductor memory device 1 and the controller 2.

The third CMOS layer 500 includes a CMOS circuit formed using the third substrate 50. The third CMOS layer 500 includes, for example, the input and output circuit 4, the logic control circuit 5, the register 6, the sequencer 7, the voltage generation circuit 8, the row decoder 9, and the sense amplifier 10. That is, in the third CMOS layer 500 of the third embodiment, the CMOS circuit that was divided into two in the first embodiment is included in one CMOS layer. The memory layer 200 includes the memory cell array 3.

In the semiconductor memory device 1, the memory layer 200 and the third CMOS layer 500 are bonded. At this time, the contact (boundary) portion of the memory layer 200 and the third CMOS layer 500 is a bonding surface. When the memory layer 200 and the third CMOS layer 500 are bonded, the memory cell array 3 in the memory layer 200 and the CMOS circuit in the third CMOS layer 500 may be sandwiched between the wiring layer and the third substrate 50. Hereinafter, bonding of the memory layer 200 and the third CMOS layer 500 is referred to as a “bonding process”.

The memory layer 200 and the third CMOS layer 500 are bonded by the bonding pad 25 and a bonding pad 55 described below contacting each other. Alternatively, the memory layer 200 and the third CMOS layer 500 are bonded by the second via contact electrode CP2 and the bonding pad 55 described below contacting each other. In addition, the bonding surface between the memory layer 200 and the third CMOS layer 500 is provided with an oxide film (not illustrated) with the bonding pad, and the memory layer 200 and the third CMOS layer 500 may be bonded by the oxide film and the bonding pad.

The semiconductor memory device 1 includes the insulating film 20, wiring layers 21 to 24, the bonding pad 25, the conductive layer 26, the diffusion prevention layer 27, the interlayer insulating film 28, the third substrate 50, wiring layers 51 to 53, the bonding pad 55, the interlayer insulating film 58, the first via contact electrode CP1, the second via contact electrode CP2, the third via contact electrode CP3, the transistor TR3, and an external pad PD3.

The memory layer 200 includes external pad PD3, the insulating film 20, wiring layers 21 to 24, the bonding pad 25, the conductive layer 26, the diffusion prevention layer 27, the interlayer insulating film 28, the memory pillar MP, the first via contact electrode CP1, the second via contact electrode CP2, and the third via contact electrode CP3.

A plurality of external pads PD3 is provided in the peripheral regions RP in the memory layer 200.

The external pad PD3 is electrically connected to the first via contact electrode CP1 and the second via contact electrode CP2 described below, and supplies a voltage to the CMOS circuit formed in the third CMOS layer 500.

The insulating film 20, the wiring layers 21 to 24, the bonding pad 25, the conductive layer 26, the diffusion prevention layer 27, the interlayer insulating film 28, and the memory pillar MP are similar to the first embodiment, and thus the descriptions thereof will be omitted.

The first via contact electrode CP1 is formed in the peripheral region RP in the memory layer 200. The first via contact electrode CP1 may be similar to the first embodiment. The first via contact electrode CP1 is electrically connected to the external pad PD3, and is also electrically connected to the second via contact electrode CP2 described below. The first via contact electrode CP1 and the second via contact electrode CP2 supply a voltage from the external pad PD3 to the third CMOS layer 500.

The first via contact electrode CP1 is formed in the peripheral region RP as in the first embodiment and has a height of at least half or more of the height in the Z direction in the first stacked body 29A. More specifically, the first via contact electrode CP1 has a height substantially the same as the height in the Z direction in the first stacked body 29A.

The second via contact electrode CP2 is formed in the peripheral region RP in the memory layer 200.

At the second via contact electrode CP2, the diameter of the surface facing the first via contact electrode CP1 is greater than the diameter of the surface facing the second via contact electrode CP2 at the first via contact electrode CP1.

The second via contact electrode CP2 contacts the bonding pad 55 of the third CMOS layer 500 described below on a surface opposite to the surface that contacts the conductive layer 26. That is, the second via contact electrode CP2 has a structure that penetrates the part of the memory layer 200 in the Z direction. In other words, the second via contact electrode CP2 has a height of at least half or more of the height in the Z direction of the second stacked body 29B described below. More specifically, the second via contact electrode CP2 has a height that is almost the same as the height from the second stacked body 29B to the bonding surfaces of the memory layer 200 and the third CMOS layer 500 in the Z direction. That is, the second via contact electrode CP2 has a height that is greater than the height of the second stacked body 29B in the Z direction.

The third via contact electrode CP3 may be similar to the first embodiment and a plurality of third via contact electrodes is disposed in the memory region RM.

The first stacked body 29A and the second stacked body 29B in the memory region RM may be similar to the first embodiment.

The third CMOS layer 500 includes the third substrate 50, the wiring layers 51 to 53, the bonding pad 55, the interlayer insulating film 58, the oxide film 59, and the transistor TR3.

The third substrate 50 may be similar to the first substrate 30 or the second substrate 40, and thus the descriptions thereof will be omitted.

The wiring layers 51 to 53 are provided in the interlayer insulating film 58 described below, and in order from the third substrate 50 side, the wiring layer 51, the wiring layer 52, and the wiring layer 53 are formed. The wiring layers 51 to 53 are provided with the wiring of the third CMOS layer 500.

In the semiconductor memory device 1, the wiring layers 51 to 53 provided in the memory region RM are electrically connected to the wiring layers 23 and 24 and the like of the memory layer 200 through the bonding pads 25 and 55.

The plurality of wiring layers 51 to 53 may include, for example, a barrier conductive film such as titanium nitride and a stacked film of a metal film such as tungsten. Alternatively, the plurality of wiring layers 51 to 53 may include, for example, a barrier conductive film such as titanium nitride, a stacked film of tantalum and tantalum nitride, and a metal film such as copper.

The plurality of pieces of wiring included in the bonding pad 55 is electrically connected, for example, to at least one of the configuration in the third CMOS layer 500 and the configuration in the memory layer 200. The bonding pad 55 includes a plurality of bonding pads. The plurality of bonding pads may include, for example, a barrier conductive film such as titanium nitride and a stacked film of a metal film such as copper. It should be noted that hereinafter, one bonding pad included in the third CMOS layer 500 may be described as the bonding pad 55, or a plurality of bonding pads included in the third CMOS layer 500 may be described as the bonding pad 55.

The bonding pad 55 is bonded to the memory layer 200 and the third CMOS layer 500 by contacting the bonding pad 25 at the bonding surface between the memory layer 200 and the third CMOS layer 500.

The interlayer insulating film 58 is provided on the third substrate 50. The interlayer insulating film 58 covers the circuits (for example, the wiring layers 51 to 53) provided on the third substrate 50. The interlayer insulating film 58 may include a plurality of insulating layers.

The transistor TR3 includes a MOSFET structure including a gate electrode, a source/drain region, and the like. The source/drain region of the MOSFET is electrically connected to the bonding pad 55 by the wiring layers 51 to 53.

FIGS. 30 to 34 are cross-sectional views illustrating an example of a cross-sectional structure during manufacturing of the memory layer 200 according to the third embodiment.

Since an example of manufacturing from FIG. 30 is the same as FIGS. 5 to 12 of the first embodiment, descriptions will be omitted.

As illustrated in FIG. 30, the third via contact hole CP3′ is formed in the memory region RM. A hole is also formed on the memory pillar MP to form a via plug that is electrically connected to the memory pillar MP. The insulating film formed on the memory layer 200 formed in FIG. 30 is included in the interlayer insulating film 28.

As illustrated in FIG. 31, a material containing tungsten is embedded in the hole on the third via contact hole CP3′ and the memory pillar MP to form the third via contact electrode CP3 and the via plug. Further, an insulating film, the wiring layers 23 to 24, a via plug, and the bonding pad 25 are formed on the interlayer insulating film 28. The insulating film further formed in FIG. 31 is included in the interlayer insulating film 28. In this manner, the wiring layers 23 to 24, the via plug, and the bonding pad 25 are formed, and the memory layer 200 is electrically connected to the third CMOS layer 500 described below.

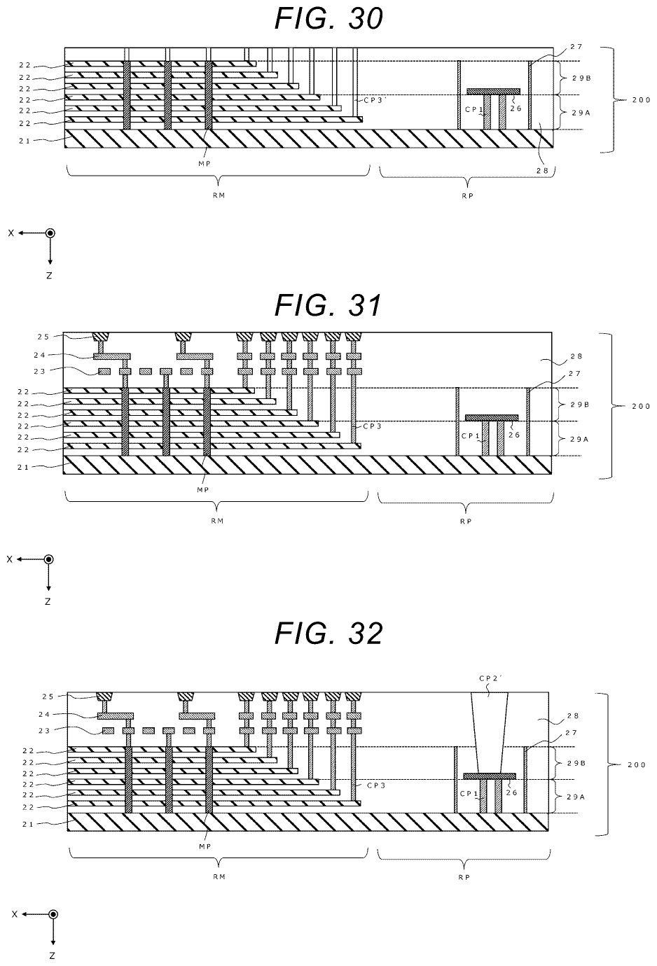

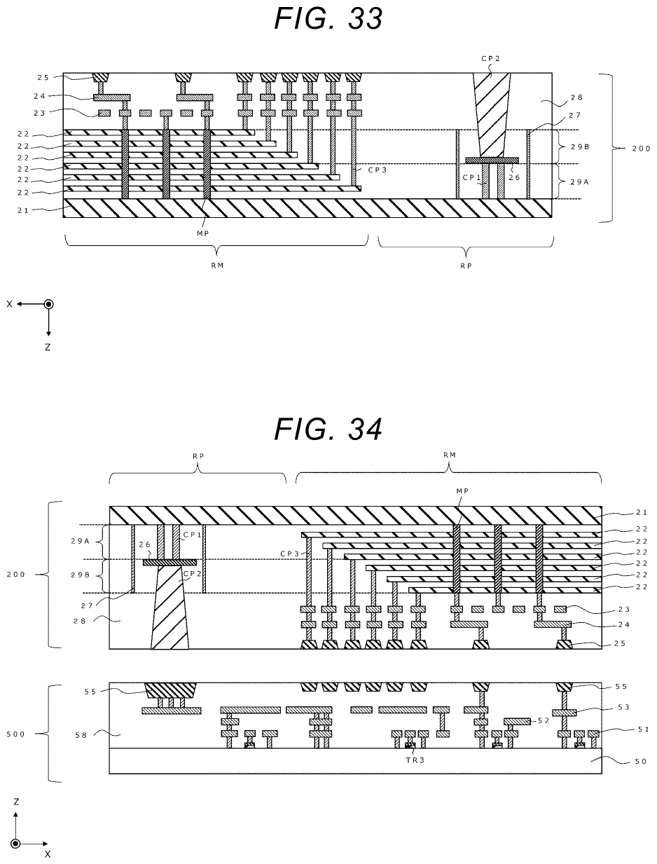

As illustrated in FIG. 32, the second via contact hole CP2′ is formed in the peripheral region RP of the memory layer 200. The second via contact hole CP2′ is formed from the bonding pad 25 side of the memory layer 200, and is formed up to the conductive layer 26 of the memory layer 200. In other words, the second via contact hole CP2′ is formed by anisotropic etching to penetrate a part of the interlayer insulating film 28 to reach the conductive layer 26.

As illustrated in FIG. 33, a material containing copper is embedded in the second via contact hole CP2′ to form the second via contact electrode CP2.

When embedding a material containing copper in the second via contact hole CP2′, since the diffusion prevention layer 27 is provided to surround the second via contact hole CP2′, the diffusion of copper can be prevented in other regions in the memory layer 200.

FIGS. 34 to 35 are cross-sectional views illustrating an example of the bonding process of the memory layer 200 and the third CMOS layer 500 according to the third embodiment.

As illustrated in FIG. 34, the memory layer 200 and the third CMOS layer 500 are arranged so as to face each other. In other words, the memory layer 200 and the third CMOS layer 500 are arranged such that the bonding pad 25 formed in the memory layer 200 and the bonding pad 55 formed in the third CMOS layer 500 face each other.

As illustrated in FIG. 35, the bonding process is performed, and the memory layer 200 and the third CMOS layer 500 are bonded. The bonding pad 25 and the bonding pad 55 correspond respectively, and the bonding pad 25 and the bonding pad 35 are electrically connected. This causes the memory layer 200 and the third CMOS layer 500 to be electrically connected. In addition, the memory layer 200 and the third CMOS layer 500 may be bonded by contacting the bonding pad 25 and the oxide film (not illustrated) included in the layer where the bonding pad 55 is formed. At this time, in the peripheral region RP, the second via contact electrode CP2 contacts the bonding pad 55 and is electrically connected.

After that, the insulating film 20 and the external pad PD3 are formed on the wiring layer 21 of the memory layer 200 by etching the wiring layer 21, resulting in the configuration as illustrated in FIG. 29.

The insulating film 20 is formed to surround the external pad PD3 when viewed from the Z direction, and is electrically insulated from the wiring layer 21 and the external pad PD3 by the insulating film 20.

The external pad PD3 is electrically connected to the first via contact electrode CP1 and the second via contact electrode CP2, thereby electrically connecting the external pad PD3 and the third CMOS layer 500. That is, a voltage can be supplied from the external pad PD3 to the third CMOS layer 500.

In the third embodiment, similarly to the first embodiment, a voltage can be efficiently supplied to the third CMOS layer 500 by using the second via contact electrode CP2, which has lower resistance than other via contact electrodes.

In the third embodiment, the same effect as in the first embodiment can be obtained. In addition, when the wiring layer 22 is highly stacked in the present embodiment, since the proportion of the second via contact electrode CP2 is relatively large as it is stacked, the resistance when supplying a voltage from the external pad PD to the third CMOS layer 500 is relatively low.

### Modification

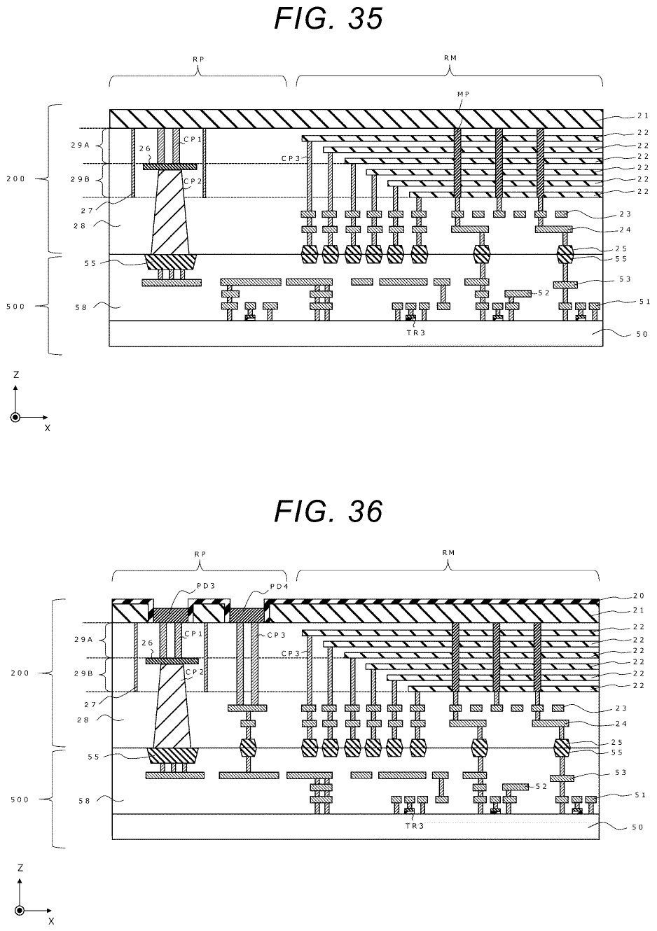

FIG. 36 is a cross-sectional view illustrating an example of a configuration of the semiconductor memory device 1 according to a modification of the third embodiment.

The semiconductor memory device 1 according to the present modification differs in that the semiconductor memory device 1 according to the third embodiment and the peripheral region RP are provided with the third via contact electrode CP3 and the external pad PD4. Since other examples of configurations may be similar to the semiconductor memory device 1 according to the third embodiment, descriptions will be omitted.

The external pad PD4 is provided in the peripheral region RP in the memory layer 200 and supplies a voltage to the CMOS circuit formed in the third CMOS layer 500 as well as the external pad PD3. Hereinafter, the external pads PD3 to PD4 may be described as the external pad PD.

A part of the third via contact electrode CP3 is disposed in the peripheral region RP, and is electrically connected to the external pad PD4. At this time, a plurality of third via contact electrodes CP3 may be electrically connected to one external pad PD4. The third via contact electrode CP3 disposed in the peripheral region RP electrically connects the external pad PD4 and the third CMOS layer 500 through the wiring layer 23, the wiring layer 24, and the bonding pad 25. That is, a voltage is supplied from the external pad PD4 to the third CMOS layer 500 through the third via contact electrode CP3.

The height in the Z direction of the third via contact electrode CP3 disposed in the peripheral region RP is greater than the first via contact electrode CP1 in the Z direction.

In the peripheral region RP of the semiconductor memory device 1 of the present modification, a plurality of external pads PD3 to PD4 are formed. The external pad PD3 is electrically connected to the third CMOS layer 500 through the first via contact electrode CP1 and the second via contact electrode CP2, and the external pad PD4 is electrically connected to the third CMOS layer 500 through the third via contact electrode CP3. Accordingly, the voltage supply to the third CMOS layer 500 may be performed through the first via contact electrode CP1 and the second via contact electrode CP2, or may be performed through the third via contact electrode CP3.

In this modification, the same effect as in the third embodiment can be obtained.

Further, as described above, in the peripheral region RP of the semiconductor memory device 1, the external pad PD and the third CMOS layer 500 are electrically connected by two types of connection methods (the first via contact electrode CP1, the second via contact electrode CP2, or the third via contact electrode CP3). The third via contact electrode CP3 can be formed in a smaller range than the second via contact electrode CP2 because of the smaller diameter in the XY plane than the second via contact electrode CP2.

The electrical connection between the external pad PD and the third CMOS layer 500 is performed by two types of methods: the connection by the first via contact electrode CP1 and the second via contact electrode CP2, and the connection by the third via contact electrode CP3. This results in a lower resistivity at the time of voltage supply than when all are connected with the third via contact electrode CP3. In addition, it is less space than connecting all the first via contact electrode CP1 and the second via contact electrode CP2, and more via contact electrodes can be formed.

### Fourth Embodiment

The semiconductor memory device of the fourth embodiment includes a memory cell and a CMOS circuit for accessing the memory cell. The semiconductor memory device has a structure in which a CMOS circuit is disposed on a stacked substrate. Hereinafter, details of the fourth embodiment will be described.

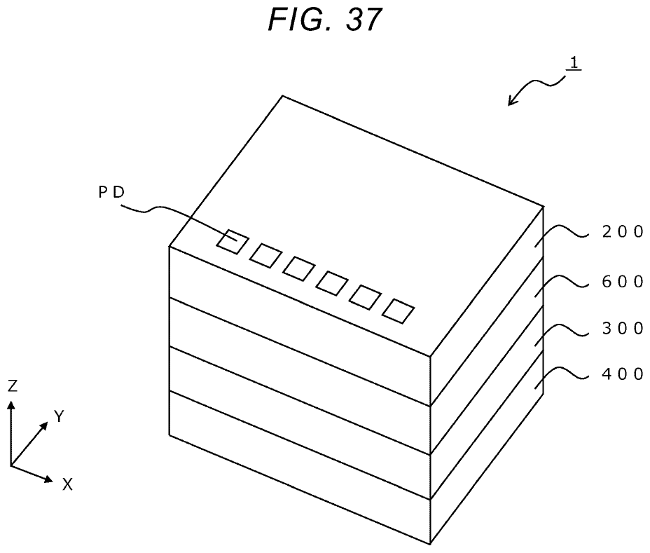

FIG. 37 is a perspective view illustrating an example of the appearance of the semiconductor memory device 1 according to the fourth embodiment. The fourth embodiment is different from the first embodiment in that it has two memory layers 200 and 600, and two CMOS layers 300 and 400. The semiconductor memory device 1 has a structure in which the memory layer 200, the second memory layer 600, the first CMOS layer 300, and the second CMOS layer 400 are stacked in order, for example, from top to bottom in the Z direction.

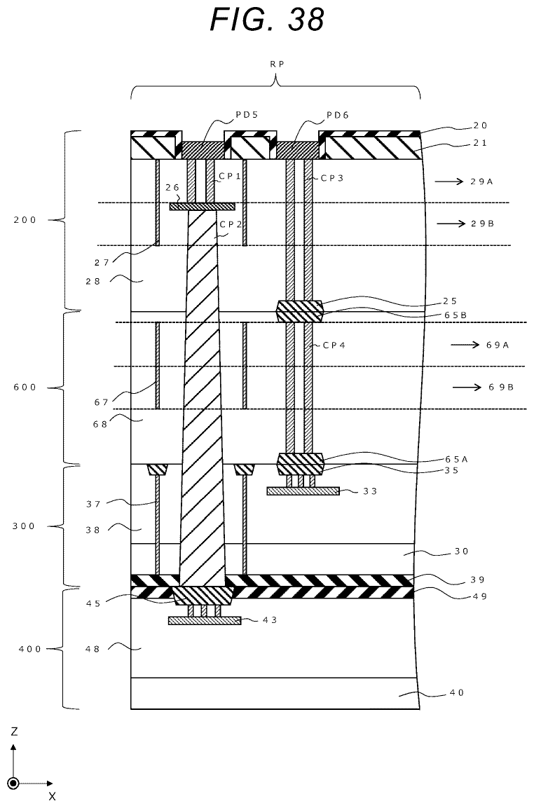

In the Z direction, the first CMOS layer 300 and the second CMOS layer 400 may each include, under the CMOS layer, the first substrate 30 and the second substrate 40 illustrated in FIG. 38 and the like, which are described below. In addition, the memory layer 200 may also have a wiring layer on the memory layer in the Z direction. It should be noted that the wiring layer in the memory layer 200 includes the layer formed after the bonding process of the memory layer 200, the second memory layer 600, the first CMOS layer 300, and the second CMOS layer 400, which will be described below. The wiring layer and the external pad PD in the memory layer may be the same as in the first embodiment.

The memory layer 200, the first CMOS layer 300, and the second CMOS layer 400 may be similar to the first embodiment. The second memory layer 600 includes the memory cell array 3.

In the semiconductor memory device 1, the memory layer 200, the second memory layer 600, the first CMOS layer 300, and the second CMOS layer 400 are bonded. At this time, each of the contact (boundary) portion between the memory layer 200 and the second memory layer 600, the contact (boundary) portion between the second memory layer 600 and the first CMOS layer 300, and the contact (boundary) portion between the second CMOS layer 400 and the first substrate is a bonding surface.

FIG. 38 is a cross-sectional view illustrating an example of a configuration of the semiconductor memory device 1 according to the fourth embodiment. Specifically, FIG. 38 illustrates the configuration of the peripheral region RP in the semiconductor memory device 1.

The memory layer 200 and the second memory layer 600 are bonded by the bonding pad 25 described below and a bonding pad 65B described below contacting each other. In addition, the bonding surface between the memory layer 200 and the second memory layer 600 is provided with the bonding pad and an oxide film (not illustrated), and may be bonded by the oxide film and the bonding pad.

The second memory layer 600 and the first CMOS layer 300 are bonded by the bonding pad 65A and the bonding pad 35 described below contacting each other. In addition, the bonding surface between the second memory layer 600 and the first CMOS layer 300 is provided with the bonding pad and an oxide film (not illustrated), and may be bonded by the oxide film and the bonding pad.

The first CMOS layer 300 and the second CMOS layer 400 include the oxide films 39 and 49 on the bonding surface, respectively. The first CMOS layer 300 and the second CMOS layer 400 may be bonded by the oxide films 39 and 49 contacting each other. In the peripheral region RP, the first CMOS layer 300 and the second CMOS layer 400 may be bonded by contacting the second via contact electrode CP2 described below and the bonding pad in the second CMOS layer 400.

Hereinafter, the configuration of the peripheral region RP of the semiconductor memory device 1 will be described.

The peripheral region RP of the semiconductor memory device 1 according to the fourth embodiment includes the insulating film 20, the wiring layer 21, the bonding pad 25, the conductive layer 26, the diffusion prevention layer 27, the interlayer insulating film 28, the first substrate 30, the wiring layer 33, the interlayer insulating film 38, the oxide film 39, the second substrate 40, the wiring layer 43, the interlayer insulating film 48, the oxide film 49, the bonding pad 65A, the bonding pad 65B, the diffusion prevention layer 67, the interlayer insulating film 68, the first via contact electrode CP1, the second via contact electrode CP2, the third via contact electrode CP3, and external pads PD5 to PD6.

It should be noted that the peripheral region RP may also include the wiring layers 22 to 23, the wiring layers 31 to 32, and the wiring layers 41 to 42, as in the first embodiment. The second memory layer 600 may also include a plurality of wiring layers in the peripheral region RP.

In the fourth embodiment, the bonding process between the memory layer 200 and the second memory layer 600 describes a form in which the bonding pad 25 and the bonding pad 65B are processed so as to face each other. However, the bonding process between the memory layer 200 and the second memory layer 600 is not limited thereto, and the bonding pad 25 and the bonding pad 65A may be processed so as to face each other.

The memory layer 200 includes external pads PD5 to PD6, the insulating film 20, the wiring layer 21, the bonding pad 25, the conductive layer 26, the diffusion prevention layer 27, the interlayer insulating film 28, the first via contact electrode CP1, the second via contact electrode CP2, and the third via contact electrode CP3.

A plurality of external pads PD5 to PD6 is provided in the peripheral region RP in the memory layer 200. Hereinafter, the external pads PD5 to PD6 may be described as the external pad PD.

The external pad PD is electrically connected to the first via contact electrode CP1, which will be described below, and the second via contact electrode CP2, or the third via contact electrode CP3, and the fourth via contact electrode CP4. This supplies a voltage to the CMOS circuit formed in the first CMOS layer 300 and the second CMOS layer 400.

The insulating film 20 may be the same as in the first embodiment.

The first via contact electrode CP1 is formed in the peripheral region RP in the memory layer 200. The first via contact electrode CP1 may be similar to the first embodiment. The first via contact electrode CP1 and the second via contact electrode CP2, described below, supply a voltage from the external pad PD5 to the second CMOS layer 400.

The second via contact electrode CP2 is formed in the peripheral region RP in the memory layer 200. The second via contact electrode CP2 is electrically connected to the first via contact electrode CP1, and is electrically connected to the external pad PD5 through the first via contact electrode CP1.

Similar to the first embodiment, the diameter of the surface facing the first via contact electrode CP1 at the second via contact electrode CP2 is greater than the diameter of the surface facing the second via contact electrode CP2 at the first via contact electrode CP1.

The second via contact electrode CP2 contacts the bonding pad of the second CMOS layer 400 described below on a surface opposite to the conductive layer 26. That is, the second via contact electrode CP2 has a structure that penetrates the entirety of the first CMOS layer 300 and the second memory layer 600, which will described below, and the part of the memory layer 200 in the Z direction.

The second via contact electrode CP2 has a height of at least half or more of the height in the Z direction of the second stacked body 29B. More specifically, the second via contact electrode CP2 has a height that is almost the same as the height from the second stacked body 29B to the bonding surfaces of the first CMOS layer 300 and the second CMOS layer 400 in the Z direction. That is, in the Z direction, the height of the second via contact electrode CP2 is greater than the sum of the height of the second stacked body 29B, the height of the second memory layer 600, and the height of the first CMOS layer 300 described below.

The material included in the second via contact electrode CP2 may be similar to the first embodiment and, for example, includes a material different from the first via contact electrode CP1.

A plurality of third via contact electrodes CP3 is disposed in the memory layer 200. The third via contact electrode CP3 may be the same as the first embodiment. The third via contact electrode CP3 disposed in the peripheral region RP is electrically connected to the external pad PD6. The third via contact electrode CP3 disposed in the peripheral region RP may be connected to the wiring layers 23 and 24 (not illustrated). Further, the third via contact electrode CP3 is electrically connected to the fourth via contact electrode CP4 in the second memory layer 600 described below through the bonding pad 25 and the bonding pad 65B described below. That is, a voltage is supplied from the external pad PD6 to the first CMOS layer 300 through the third via contact electrode CP3 and the fourth via contact electrode CP4. In other words, the third via contact electrode CP3 of the peripheral region RP can supply a voltage to the CMOS layer in direct contact with the layer including the memory cell array.

The height in the Z direction of the third via contact electrode CP3 disposed in the peripheral region RP is greater than the first via contact electrode CP1 in the Z direction.

The wiring layer 21, the conductive layer 26, the diffusion prevention layer 27, and the interlayer insulating film 28 may be the same as in the first embodiment, and thus the descriptions thereof will be omitted.

The configuration of the second memory layer 600 may be substantially the same as the memory layer 200. The second memory layer 600, including the memory region RM (not illustrated), includes a wiring layer, the bonding pads 65A and 65B, the diffusion prevention layer 67, the interlayer insulating film 68, a memory pillar, the second via contact electrode CP2, and the fourth via contact electrode CP4. The second memory layer 600 has the memory cell array 3 as well as the memory layer 200. In other words, the semiconductor memory device 1 of the fourth embodiment has a structure in which a plurality of memory layers, each including the memory cell array 3, is stacked.

In the peripheral region RP, the second memory layer 600 includes the bonding pad 65A, the bonding pad 65B, the diffusion prevention layer 67, the interlayer insulating film 68, the second via contact electrode CP2, and the fourth via contact electrode CP4.

The second via contact electrode CP2 is formed in the peripheral region RP in the second memory layer 600, and has a structure that penetrates the second memory layer 600 in the Z direction.

A plurality of fourth via contact electrodes CP4 is disposed in the second memory layer 600. The fourth via contact electrode CP4 may have a similar structure to the third via contact electrode CP3 in the memory layer 200. At this time, a plurality of fourth via contact electrodes CP4 may be electrically connected to one external pad PD6. The fourth via contact electrode CP4 disposed in the peripheral region RP may also be connected to the bonding pad 65A or the bonding pad 65B via the wiring layer (not illustrated).

The fourth via contact electrode CP4 is electrically connected to the bonding pad 65A and the bonding pad 65B, and is electrically connected to the external pad PD6 and the first CMOS layer 300. That is, in the peripheral region RP, the third via contact electrode CP3 and the fourth via contact electrode CP4 supply a voltage from the external pad PD6 to the first CMOS layer 300. In other words, the fourth via contact electrode CP4 of the peripheral region RP can supply a voltage to the CMOS layer in direct contact with the layer including the memory cell array.

The height in the Z direction of the fourth via contact electrode CP4 disposed in the peripheral region RP is greater than that of the first via contact electrode CP1 in the Z direction.

The fourth via contact electrode CP4 contains, for example, tungsten.

The plurality of pieces of wiring included in the bonding pad 65A is electrically connected, for example, to at least one of the configuration in the first CMOS layer 300 and the configuration in the second memory layer 600 described below. The plurality of pieces of wiring included in the bonding pad 65B is also electrically connected, for example, to at least one of the configuration in the memory layer 200 and the configuration in the second memory layer 600. Specifically, the bonding pad 65A in the peripheral region RP is electrically connected to the bonding pad 35 in the first CMOS layer 300. The bonding pad 65B in the peripheral region RP is electrically connected to the bonding pad 25 in the memory layer 200.

The bonding pad 65A and the bonding pad 65B include a plurality of bonding pads. The plurality of bonding pads 65A and 65B may include, for example, a barrier conductive film such as titanium nitride and a stacked film of a metal film such as copper. It should be noted that hereinafter, one bonding pad included in the second memory layer 600 may be described as the bonding pad 65A, or a plurality of bonding pads included in the second memory layer 600 may be described as the bonding pad 65A. The bonding pad 65B is the same as the bonding pad 65A.

The interlayer insulating film 68 fills the second memory layer 600 and insulates other elements from each other. The interlayer insulating film 68 is, for example, a silicon oxide film or a silicon nitride film.

The second memory layer 600 also includes the fourth stacked body 69A and the fifth stacked body 69B in the memory region RM (not illustrated). The memory region RM in the second memory layer 600 is included, for example, in the third region.

The fourth stacked body 69A and the fifth stacked body 69B also have a structure in which a plurality of insulating layers and a plurality of wiring layers are alternately stacked in the memory region RM (not illustrated), similar to the first stacked body 29A and the second stacked body 29B. The plurality of wiring layers are formed in a stepped manner in the Z direction, and the fifth stacked body 69B is formed below the fourth stacked body 69A. The fourth stacked body 69A and the fifth stacked body 69B may have the same height in the Z direction, or may have different heights.

The diffusion prevention layer 67 is provided around the second via contact electrode CP2. The diffusion prevention layer 67 may have the same structure as the diffusion prevention layer 27. That is, the second memory layer 600 (not illustrated) may have a height substantially the same as the height in the Z direction of the plurality of stacked bodies in the memory cell array 3.

The diffusion prevention layer 67 contains, for example, tungsten.

In the present embodiment, in the memory region RM (not illustrated), the slit is formed after the formation of the fourth stacked body 69A and the fifth stacked body 69B. The height in the Z direction of the diffusion prevention layer 67 is almost the same as the height in the Z direction of the slit (not illustrated) in the second memory layer 600, for example. In other words, the height of the diffusion prevention layer 67 in the Z direction is almost the same as the sum of the height of the fourth stacked body 69A in the Z direction and the height of the fifth stacked body 69B in the Z direction, for example.

The second memory layer 600 is bonded to the first CMOS layer 300 at a surface opposite to the surface to which the memory layer 200 is bonded.

The first CMOS layer 300 and the second CMOS layer 400 may be the same as that of the first embodiment, and thus the descriptions thereof will be omitted.

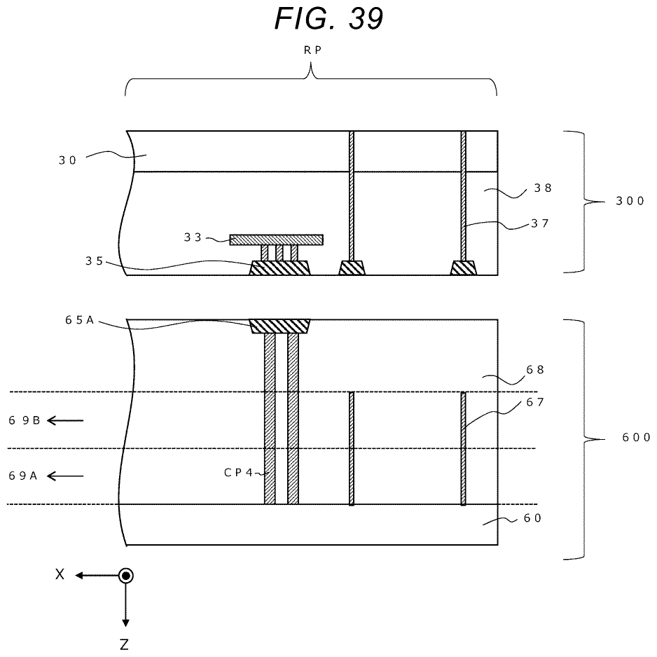

FIGS. 39 to 42 are cross-sectional views illustrating an example of the bonding process of the second memory layer 600 and the first CMOS layer 300 according to the fourth embodiment. Specifically, FIGS. 39 to 42 illustrate the configuration of the peripheral region RP in the semiconductor memory device 1.

As illustrated in FIG. 39, the second memory layer 600 and the first CMOS layer 300 are arranged so as to face each other. In other words, the second memory layer 600 and the first CMOS layer 300 are arranged such that the bonding pad 65A formed in the second memory layer 600 and the bonding pad 35 formed in the first CMOS layer 300 face each other.

At this time, the method of forming the fourth via contact electrode CP4 in the second memory layer 600 may be similar to the third via contact electrode CP3 according to the first embodiment. That is, as illustrated in FIGS. 13 to 14, after the formation of the fourth stacked body 69A and the fifth stacked body 69B, the fourth via contact electrode CP4 is formed. The method of forming the diffusion prevention layer 67 in the second memory layer 600 may also be the same as that of the diffusion prevention layer 27 in the first embodiment. That is, as illustrated in FIGS. 11 to 12, the diffusion prevention layer 67 is also formed at the timing when the slit (not illustrated) is formed in the memory region RM.

The method of forming the first CMOS layer 300 may also be the same as that of the first CMOS layer 300 in the first embodiment. That is, as illustrated in FIGS. 16 to 18, the first CMOS layer 300 is formed.

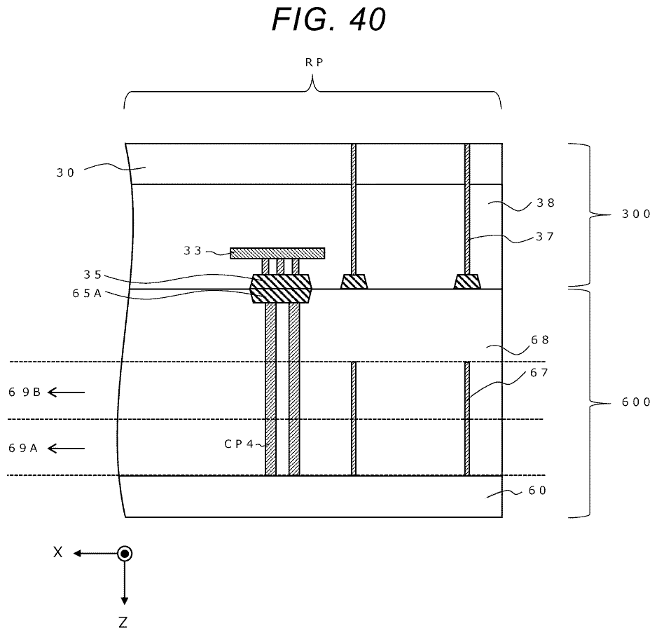

As illustrated in FIG. 40, the bonding process is performed, and the second memory layer 600 and the first CMOS layer 300 are bonded. The bonding pad 65A and the bonding pad 35 correspond respectively, and the bonding pad 65A and the bonding pad 35 are electrically connected. This makes the second memory layer 600 and the first CMOS layer 300 electrically connectable. In addition, the second memory layer 600 and the first CMOS layer 300 may be bonded by contacting the bonding pad 65A and the oxide film (not illustrated) included in the layer where the bonding pad 35 is formed.

It should be noted that after the bonding process of the second memory layer 600 and the first CMOS layer 300, the oxide film 39 may be formed on the surface opposite to the surface to which the second memory layer 600 is bonded in the first CMOS layer 300.

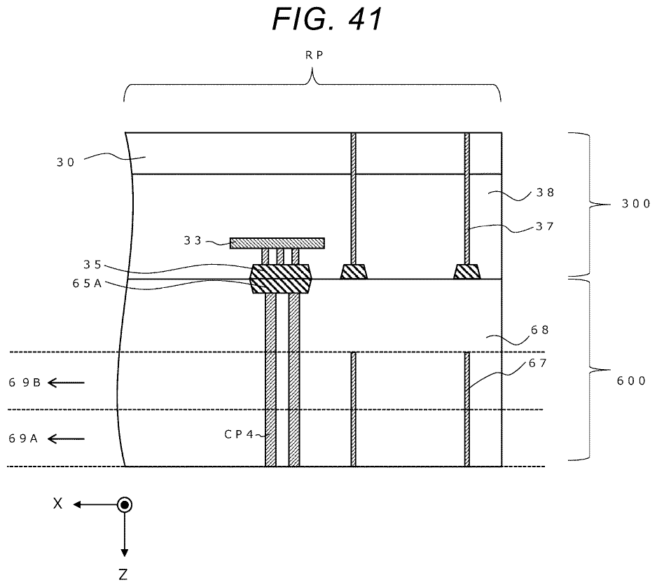

As illustrated in FIG. 41, the fourth substrate 60 is removed in the second memory layer 600. The fourth substrate 60 is removed by a pharmaceutical solution containing, for example, potassium hydroxide (KOH) or the like. The fourth substrate 60 is, for example, a silicon wafer.

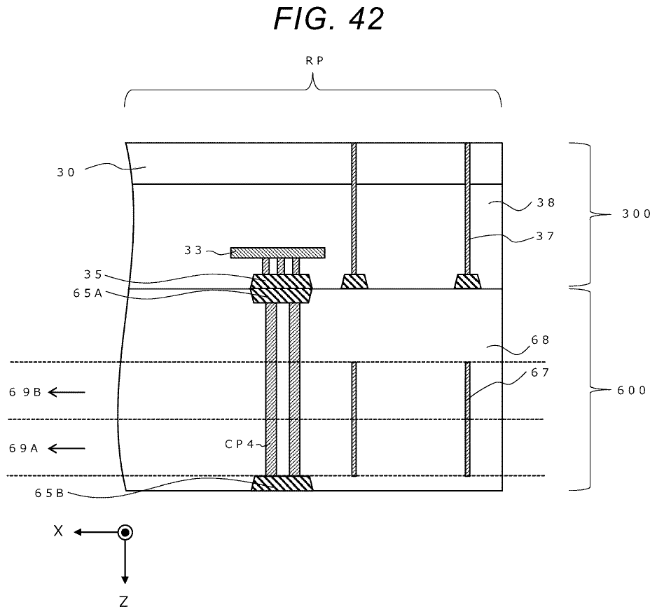

As illustrated in FIG. 42, the bonding pad 65B is formed on the exposed surface after the removal of the fourth substrate 60. The bonding pad 65B may include an insulating film such as a silicon nitride film. The bonding pad 65B forms an insulating film on the exposed surface after the removal of the fourth substrate 60, for example, to remove the insulating film in some areas. The bonding pad 65B is formed by embedding a metal or the like in the place where the insulating film is removed.

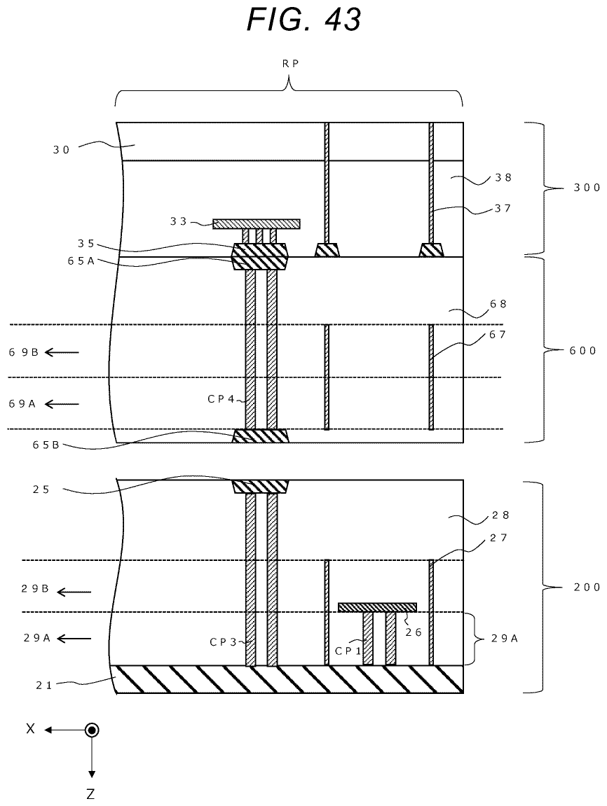

FIGS. 43 to 46 are cross-sectional views illustrating an example of the bonding process of the second memory layer 600 and the memory layer 200 according to the fourth embodiment. Specifically, FIGS. 43 to 46 illustrate the configuration of the peripheral region RP in the semiconductor memory device 1.

As illustrated in FIG. 43, the second memory layer 600 and the memory layer 200 are arranged so as to face each other. In other words, the second memory layer 600 and the memory layer 200 are arranged such that the bonding pad 65B formed in the second memory layer 600 and the bonding pad 25 formed in the memory layer 200 face each other.

The configuration of the memory layer 200 when bonded may be the same as that of the first embodiment. That is, the memory layer 200 is manufactured as in FIGS. 5 to 15.

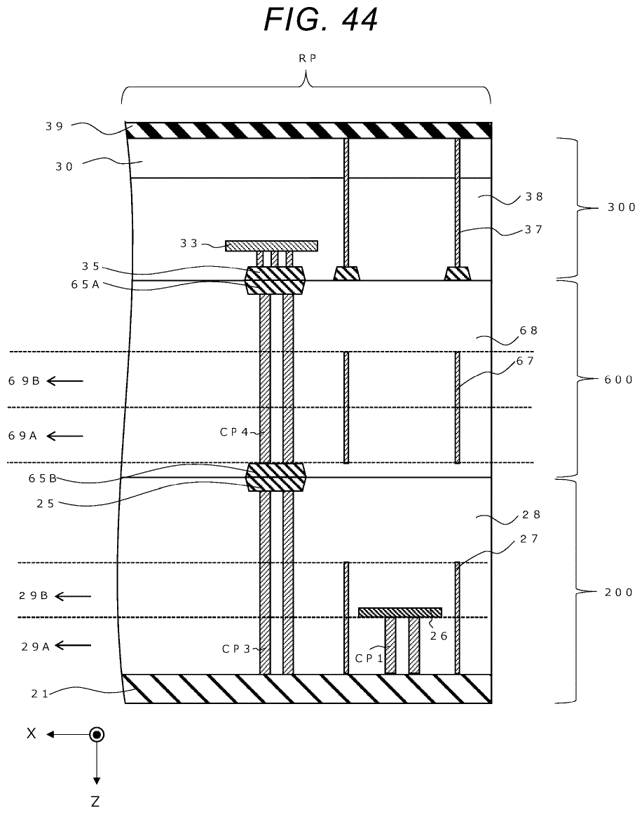

As illustrated in FIG. 44, the bonding process is performed, and the second memory layer 600 and the memory layer 200 are bonded. In addition, the oxide film 39 is formed on the surface opposite to the surface to which the second memory layer 600 is bonded in the first CMOS layer 300.

The bonding pad 65B and the bonding pad 25 correspond respectively, and the bonding pad 65B and the bonding pad 25 are electrically connected. This makes the second memory layer 600 and the memory layer 200 electrically connectable. In addition, the third via contact electrode CP3, the fourth via contact electrode CP4, and the bonding pads 25, 35, 65A, and 65B are each electrically connected, so that the memory layer 200, the second memory layer 600, and the first CMOS layer 300 can be electrically connected.

The memory layer 200 and the first CMOS layer 300 may be bonded by contacting the bonding pad 65B and the oxide film (not illustrated) included in the layer where the bonding pad 25 is formed.

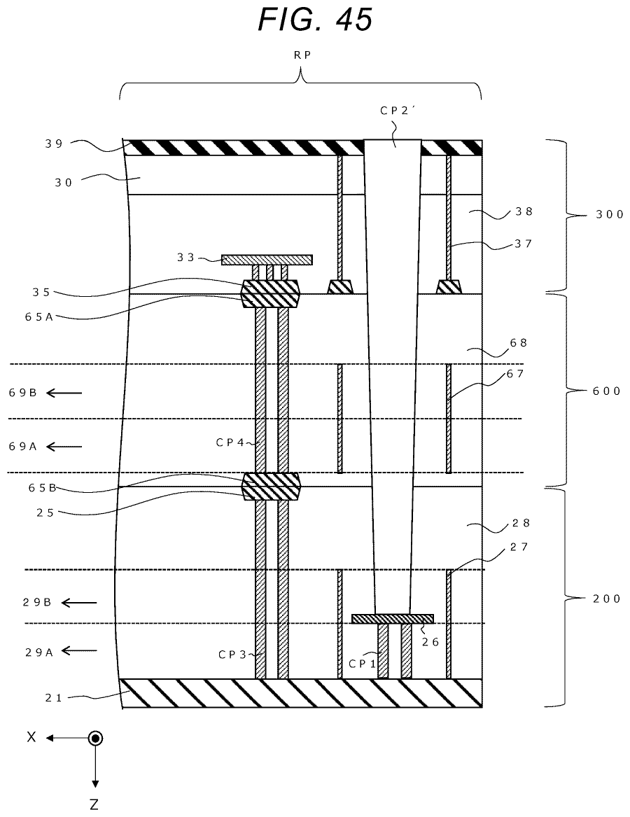

As illustrated in FIG. 45, the second via contact hole CP2′ is formed in the peripheral region RP of the memory layer 200, the second memory layer 600, and the first CMOS layer 300 after the bonding process. The second via contact hole CP2′ is formed from the oxide film 39 side of the first CMOS layer 300, penetrates the first CMOS layer 300 and the second memory layer 600, and is formed up to the conductive layer 26 of the memory layer 200. In other words, the second via contact hole CP2′ is formed by anisotropic etching to penetrate the oxide film 39, the first substrate 30, the interlayer insulating film 38, the interlayer insulating film 68, and the interlayer insulating film 28 to reach the conductive layer 26. When viewed from the negative direction of the Z direction, the second via contact hole CP2′ is formed to overlap the conductive layer 26 and the first via contact electrode CP1.

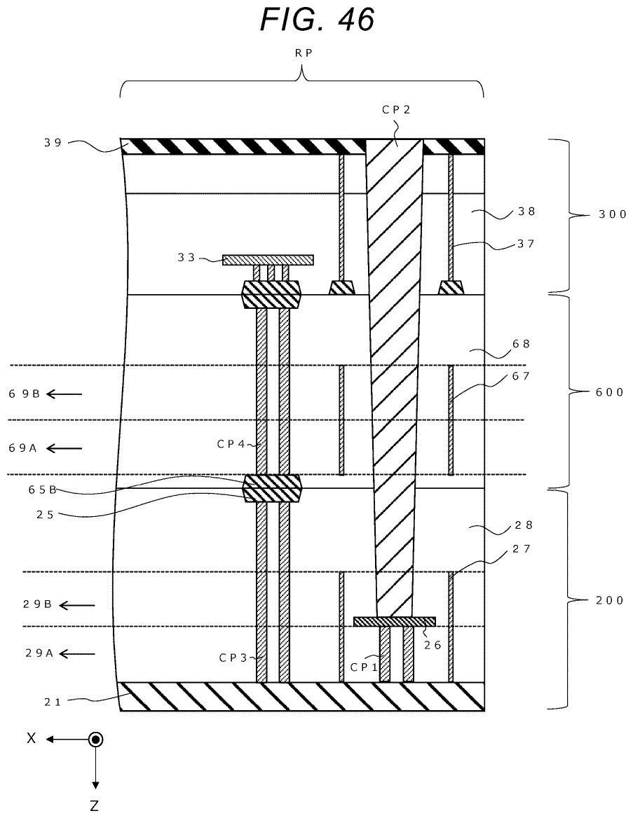

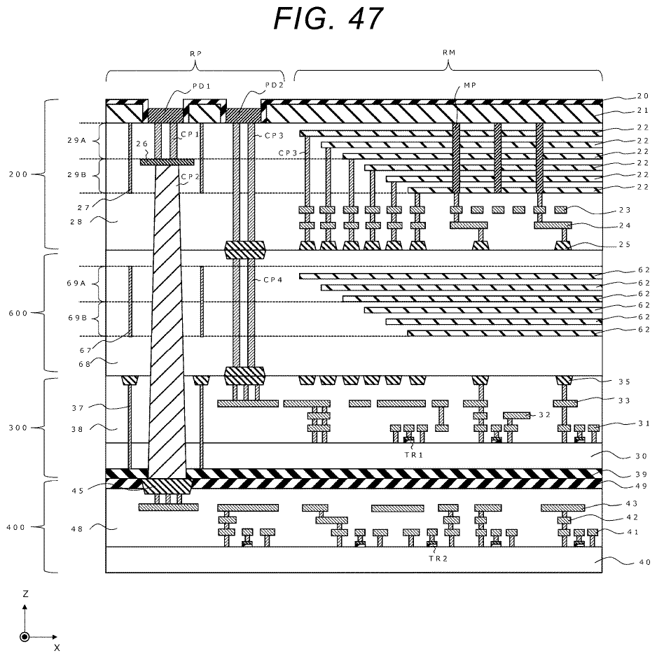

As illustrated in FIG. 46, a material containing copper is embedded in the second via contact hole CP2′ to form the second via contact electrode CP2. The second via contact electrode CP2 is formed from the oxide film 39 side of the first CMOS layer 300, penetrates the first CMOS layer 300 and the second memory layer 600, and is formed up to the conductive layer 26 of the memory layer 200.

When embedding a material containing copper in the second via contact hole CP2′, the diffusion prevention layers 27, 37, and 67 are provided to surround the second via contact hole CP2′. Accordingly, the diffusion of copper can be prevented in the memory layer 200, the second memory layer 600, and other regions in the first CMOS layer 300.

After this, the bonding process between the first CMOS layer 300 and the second CMOS layer 400 is performed, but since the bonding process is similar to FIGS. 23 to 25 of the first embodiment, descriptions will be omitted.

Thereafter, as illustrated in FIG. 38, the insulating film 20 and the external pad PD are formed on the wiring layer 21 of the memory layer 200 by etching the wiring layer 21.

By electrically connecting the external pad PD5 to the first via contact electrode CP1 and the second via contact electrode CP2, a voltage can be supplied from the external pad PD5 to the second CMOS layer 400. Furthermore, the external pad PD6, the third via contact electrode CP3, and the fourth via contact electrode CP4 are electrically connected, so that a voltage can be supplied from the external pad PD6 to the first CMOS layer 300.

FIG. 47 is a cross-sectional view illustrating an example of a configuration of the semiconductor memory device 1 according to the fourth embodiment. FIG. 47 also illustrates the configuration of the memory region RM. It should be noted that in the memory region RM in the second memory layer 600, configurations other than the wiring layer 62 are omitted.

As illustrated in FIG. 47, the memory layer 200 and the second memory layer 600 are bonded so that the second stacked body 29B and the fourth stacked body 69A described below face each other. However, the bonding process between the memory layer 200 and the second memory layer 600 is not limited thereto, and the second stacked body 29B and the fifth stacked body 69B described below may be bonded so as to face each other.

The second memory layer 600 has a plurality of wiring layers 62 in the memory region RM.

The wiring layer 62 is formed in a position overlapping the second via contact electrode CP2 and the fourth via contact electrode CP4 when viewed from the Y direction. In addition, a plurality of wiring layers 62 are spaced from each other, and the interlayer insulating film 68 is formed between adjacent wiring layers 62. In the Z direction, a structure in which a plurality of insulating layers and a plurality of wiring layers 62 are alternately stacked from the interlayer insulating film 68 formed on the source line (not illustrated) and contacting the wiring layer 62 formed uppermost in the wiring layer 62 is the fourth stacked body 69A. Further, in the Z direction, a structure which is formed below the fourth stacked body 69A and in which a plurality of insulating layers and the wiring layer 22 are alternately stacked is the fifth stacked body 69B.

The wiring layer 62 includes a plurality of word lines and a plurality of select gate lines as a plurality of electrode layers in the memory cell array 3. The wiring layer 62 has a stair structure. In addition, a plurality of memory pillars (not illustrated) are formed to penetrate the wiring layer 62. The wiring layer 62 is included, for example, in the third conductive layer or the fourth conductive layer, and the interlayer insulating film 68 formed between the plurality of wiring layers 62 in the memory region RM is included in the third insulating layer or the fourth insulating layer.

In the fourth embodiment, the same effect as in the first embodiment can be obtained.

Also, in the fourth embodiment, the second memory layer 600 is included, and the second via contact electrode CP2 has a structure that penetrates the first CMOS layer 300, the second memory layer 600, and a part of the memory layer 200 in the Z direction. Since the second via contact electrode CP2 can form a larger diameter in the XY plane than the first via contact electrode CP1, even if a plurality of memory layers are stacked, the aspect ratio is less affected.

As the number of stacked memory layers increases, the proportion of the second via contact electrode CP2 when electrically connecting the external pad PD and the second CMOS layer 400 increases. Thus, in the present embodiment, the second via contact electrode CP2 penetrates the second memory layer 600 in the Z direction, and the proportion of the second via contact electrode CP2 is relatively large, so the resistance when supplying a voltage from the external pad PD to the second CMOS layer 400 is relatively low.

### Fifth Embodiment

The semiconductor memory device of a fifth embodiment includes a memory cell and a CMOS circuit for accessing the memory cell. The semiconductor memory device has a structure in which a CMOS circuit is disposed on a stacked substrate. Hereinafter, details of the fifth embodiment will be described.

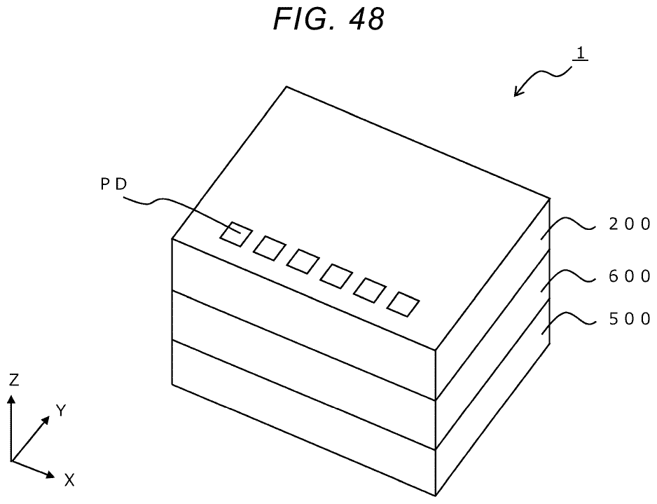

FIG. 48 is a perspective view illustrating an example of the appearance of the semiconductor memory device 1 according to the fifth embodiment.

In the fifth embodiment, two memory layers 200 and 600, and one CMOS layer 500 are included.

The semiconductor memory device 1 has a structure in which the memory layer 200, a second memory layer 600, and a third CMOS layer 500 are stacked in order, for example, from top to bottom in the Z direction.

It should be noted that the configuration of the memory layer 200 and the second memory layer 600 may be the same as that of the fourth embodiment, and thus will be briefly described. The third CMOS layer 500 is also similar to the third embodiment, and thus the descriptions thereof will be omitted.

In the Z direction, the memory layer 200 may have a wiring layer on the memory layer. The wiring layer includes, for example, a plurality of external pads PD7 used to connect the semiconductor memory device 1 and the controller 2. The external pad PD7 is connected to the input and output circuit 4 and is exposed on the surface of the semiconductor memory device 1.

The third CMOS layer 500 may be the same as the third embodiment. That is, in the third CMOS layer 500 of the fifth embodiment, the CMOS circuit that was divided into two in the first embodiment is included in one CMOS layer.

In the semiconductor memory device 1, the memory layer 200, the second memory layer 600, and the third CMOS layer 500 are bonded. At this time, each of the contact (boundary) portion between the memory layer 200 and the second memory layer 600 and the contact (boundary) portion between the second memory layer 600 and the third CMOS layer 500 is a bonding surface.

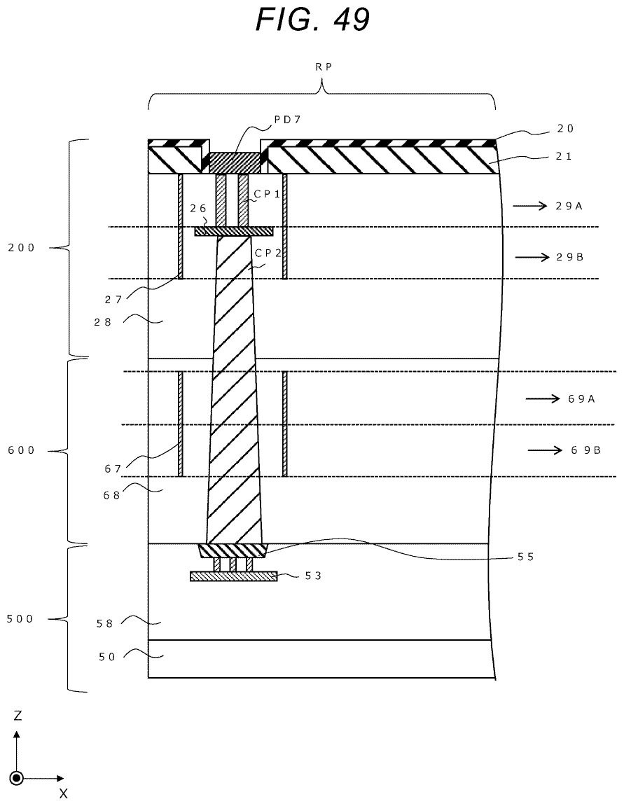

FIG. 49 is a cross-sectional view illustrating an example of a configuration of the semiconductor memory device 1 according to the fifth embodiment. Specifically, FIG. 49 illustrates the configuration of the peripheral region RP in the semiconductor memory device 1. Hereinafter, the peripheral region RP of the semiconductor memory device 1 will be described.

The memory layer 200 and the second memory layer 600 are bonded by the bonding pad (not illustrated) in the memory layer 200 and the bonding pad (not illustrated) in the second memory layer 600 contacting each other.

The second memory layer 600 and the third CMOS layer 500 are bonded in the peripheral region RP by the second via contact electrode CP2 and the bonding pad 55 described below contacting each other. In addition, the bonding surface between the memory layer 200 and the third CMOS layer 500 is provided with an oxide film (not illustrated) with the bonding pad, and the memory layer 200 and the third CMOS layer 500 may be bonded by the oxide film and the bonding pad.

The peripheral region RP of the semiconductor memory device 1 according to the fifth embodiment includes the insulating film 20, the wiring layer 21, the conductive layer 26, the diffusion prevention layer 27, the interlayer insulating film 28, the third substrate 50, the wiring layer 53, the interlayer insulating film 58, the diffusion prevention layer 67, the interlayer insulating film 68, the first via contact electrode CP1, the second via contact electrode CP2, and the external pad PD7.

In the fifth embodiment, the bonding process between the memory layer 200 and the second memory layer 600 describes a form that is processed in the same manner as the fourth embodiment. However, the bonding process between the memory layer 200 and the second memory layer 600 is not limited thereto.

The memory layer 200 includes the external pad PD7, the insulating film 20, the wiring layer 21, the conductive layer 26, the diffusion prevention layer 27, the interlayer insulating film 28, the first via contact electrode CP1, and the second via contact electrode CP2.

A plurality of external pads PD7 is provided in the peripheral region RP in the memory layer 200.

The external pad PD7 is electrically connected to the first via contact electrode CP1 and the second via contact electrode CP2 described below, and supplies a voltage to the CMOS circuit formed in the third CMOS layer 500.

The insulating film 20 may be the same as in the first embodiment.

The first via contact electrode CP1 may also be similar to the first embodiment and has a height of at least half or more of the height in the Z direction in the first stacked body 29A. The voltage is supplied from the external pad PD7 to the third CMOS layer 500 through the first via contact electrode CP1 and the second via contact electrode CP2 described below.

The second via contact electrode CP2 is formed in the peripheral region RP in the memory layer 200. The second via contact electrode CP2 is electrically connected to the first via contact electrode CP1, and is electrically connected to the external pad PD7 through the first via contact electrode CP1.

Similar to the first embodiment, the diameter of the surface facing the first via contact electrode CP1 at the second via contact electrode CP2 is greater than the diameter of the surface facing the second via contact electrode CP2 at the first via contact electrode CP1.

The second via contact electrode CP2 may contact the bonding pad 55 of the third CMOS layer 500 on a surface opposite to the surface that contacts the conductive layer 26. In this case, the second via contact electrode CP2 has a structure that penetrates the entirety of the second memory layer 600 described below, and a part of the memory layer 200 in the Z direction. The second via contact electrode CP2 has a height of at least half or more of the height in the Z direction of the second stacked body 29B described below. More specifically, the second via contact electrode CP2 has a height that is almost the same as the height from the second stacked body 29B to the bonding surfaces of the second memory layer 600 and the third CMOS layer 500 in the Z direction. That is, in the Z direction, the height of the second via contact electrode CP2 is greater than the sum of the height of the second stacked body 29B and the height of the second memory layer 600 described below.

The material included in the second via contact electrode CP2 may be the same as in the first embodiment.

The conductive layer 26, the diffusion prevention layer 27, and the interlayer insulating film 28 may be the same as in the first embodiment, and thus the descriptions thereof will be omitted.

The configuration of the second memory layer 600 may be the same as that of the fourth embodiment, and thus will be briefly described.

In the peripheral region RP, the second memory layer 600 includes the diffusion prevention layer 67, the interlayer insulating film 68, and the second via contact electrode CP2. Alternatively, a bonding pad (not illustrated) may be included.

The diffusion prevention layer 67 and the interlayer insulating film 68 may be the same as in the fourth embodiment, and thus the descriptions thereof will be omitted.

The second memory layer 600 includes the fourth stacked body 69A and the fifth stacked body 69B in the memory region RM (not illustrated). The fourth stacked body 69A and the fifth stacked body 69B may also be the same as the fourth embodiment.

The second memory layer 600 is bonded to the third CMOS layer 500 at a surface opposite to the surface to which the memory layer 200 is bonded.

The third CMOS layer 500 may be the same as the third embodiment, and thus the description thereof will be omitted.

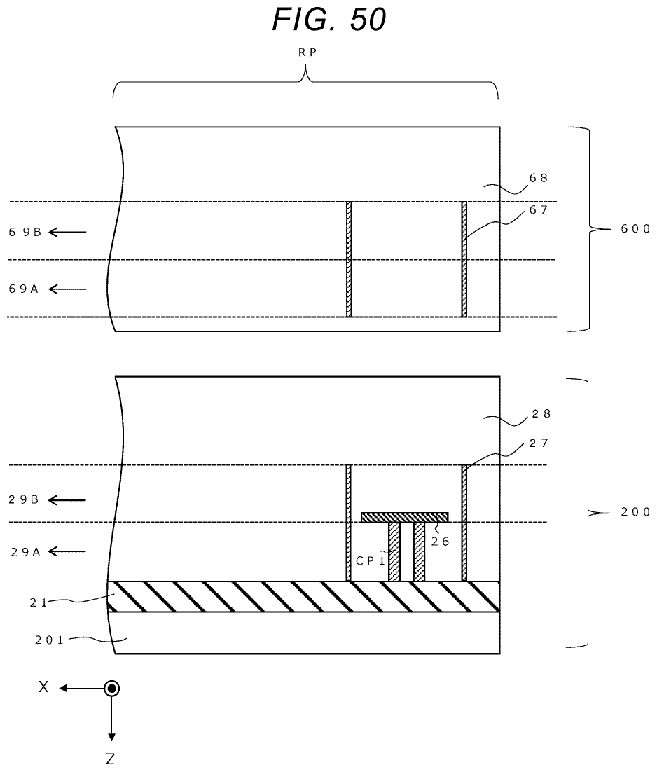

FIGS. 50 to 53 are cross-sectional views illustrating an example of the bonding process of the memory layer 200 and the second memory layer 600 according to the fifth embodiment. Specifically, FIGS. 50 to 53 illustrate the configuration of the peripheral region RP in the semiconductor memory device 1.

The configuration of the memory layer 200 when bonded may be the same as that of the first embodiment. That is, the memory layer 200 is manufactured as in FIGS. 5 to 15. The configuration of the second memory layer 600 when bonded may be the same as the fourth embodiment. The method of forming the diffusion prevention layer 67 in the second memory layer 600 may also be the same as that of the diffusion prevention layer 27 in the first embodiment. That is, as illustrated in FIGS. 11 to 12, the diffusion prevention layer 67 is also formed at the timing when the slit (not illustrated) is formed in the memory region RM.

As illustrated in FIG. 50, the memory layer 200 and the second memory layer 600 are arranged so as to face each other. In other words, the memory layer 200 and the second memory layer 600 are arranged such that the second stacked body 29B formed in the memory layer 200 and the fourth stacked body 69A formed in the second memory layer 600 face each other.

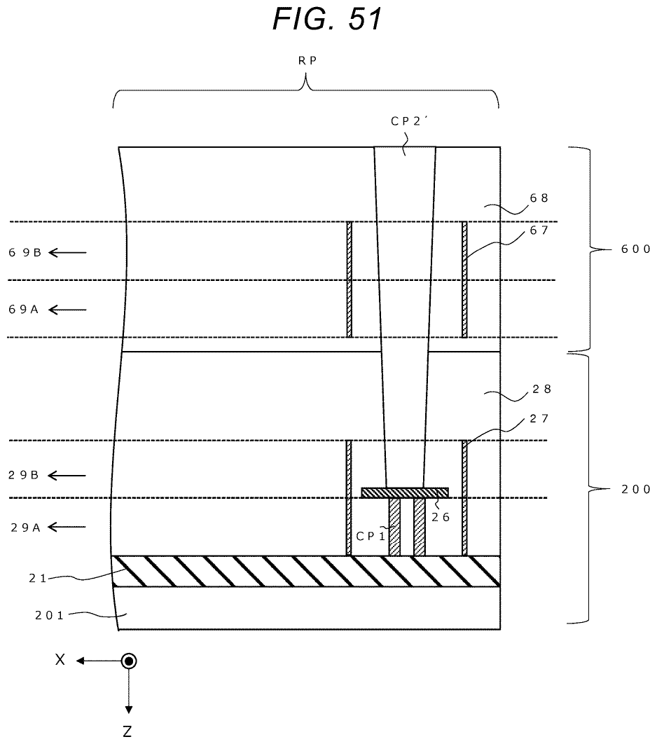

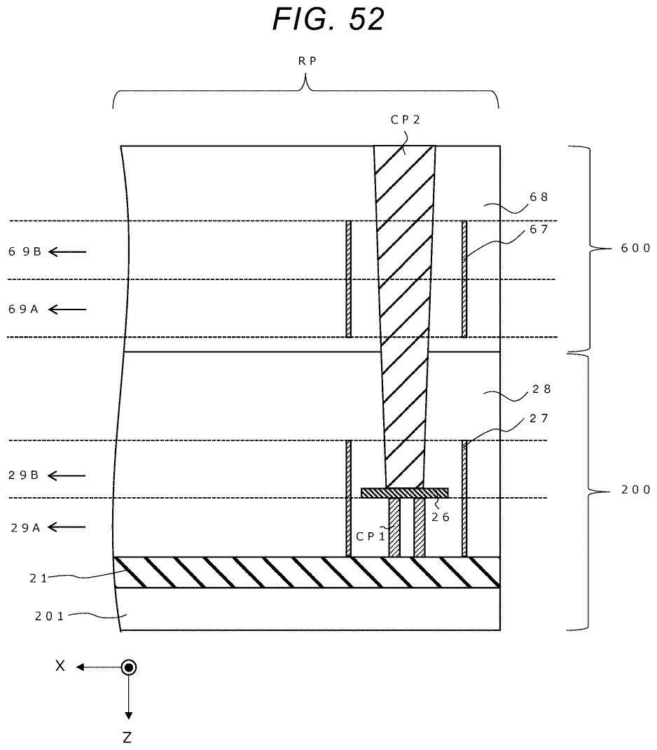

After the memory layer 200 and the second memory layer 600 are bonded, the second via contact hole CP2′ is formed in the memory layer 200 after the bonding process and the peripheral region RP of the second memory layer 600, as illustrated in FIG. 51. The second via contact hole CP2′ is formed by anisotropic etching to penetrate the interlayer insulating film 68 and a part of the interlayer insulating film 28 in the Z direction to reach the conductive layer 26. When viewed from the negative direction of the Z direction, the second via contact hole CP2′ is formed to overlap the conductive layer 26 and the first via contact electrode CP1.

As illustrated in FIG. 52, a material containing copper is embedded in the second via contact hole CP2′ to form the second via contact electrode CP2. The second via contact electrode CP2 is formed from a surface opposite to the surface to which the memory layer 200 is bonded in the second memory layer 600, penetrates the second memory layer 600, and is formed up to the conductive layer 26 of the memory layer 200.

When embedding a material containing copper in the second via contact hole CP2′, since the diffusion prevention layers 27 and 67 are provided to surround the second via contact hole CP2′, the diffusion of copper can be prevented in other regions in the memory layer 200 and the second memory layer 600.

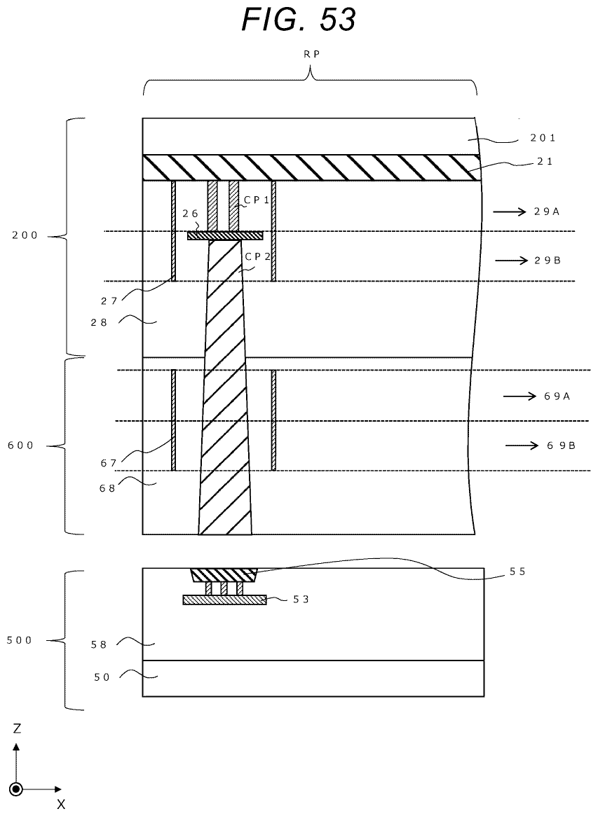

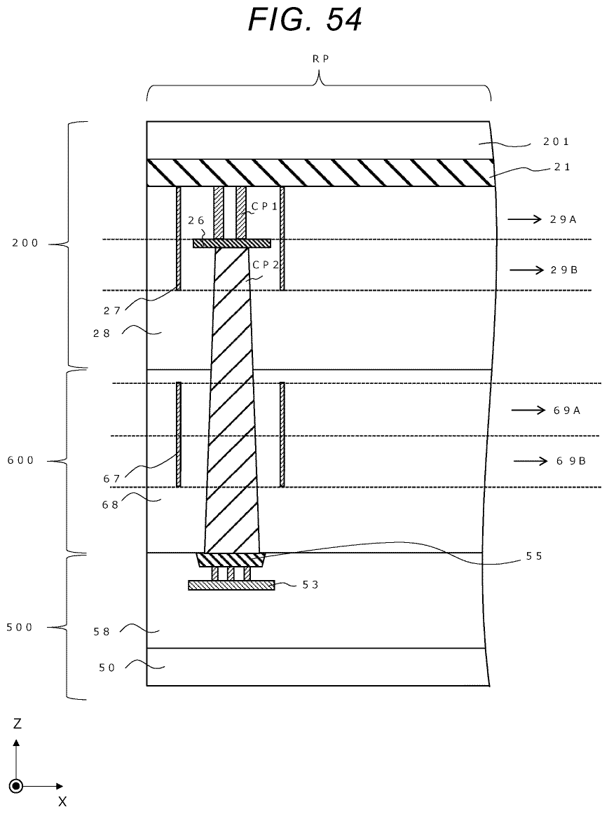

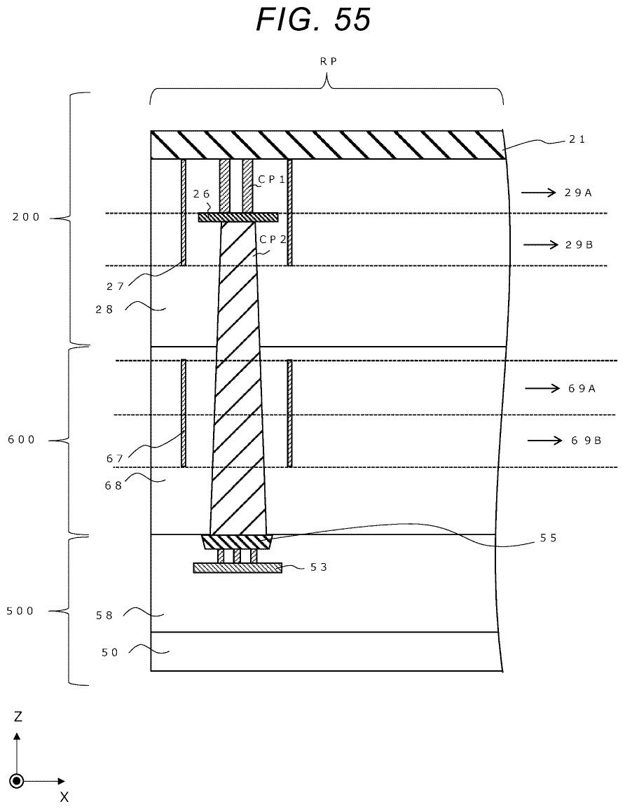

FIGS. 53 to 55 are cross-sectional views illustrating an example of the bonding process of the second memory layer 600 and the third CMOS layer 500 according to the fifth embodiment. Specifically, FIGS. 54 to 56 illustrate the configuration of the peripheral region RP in the semiconductor memory device 1.

As illustrated in FIG. 53, the second memory layer 600 and the third CMOS layer 500 are arranged so as to face each other. In other words, the second memory layer 600 and the third CMOS layer 500 are arranged such that the surface opposite to the surface to which the memory layer 200 is bonded in the second memory layer 600 and the bonding pad in the bonding pad 55 formed in the third CMOS layer 500 face each other.

As illustrated in FIG. 54, the bonding process is performed, and the second memory layer 600 and the third CMOS layer 500 are bonded. At this time, the second via contact electrode CP2 and the bonding pad 55 are electrically connected.

As illustrated in FIG. 55, the fifth substrate 201 is removed in the memory layer 200. The fifth substrate 201 is removed by a pharmaceutical solution containing, for example, potassium hydroxide (KOH) or the like. The fifth substrate 201 is, for example, a silicon wafer.

Thereafter, as illustrated in FIG. 49, the insulating film 20 and the external pad PD7 are formed on the wiring layer 21 of the memory layer 200 by etching the wiring layer 21.

The external pad PD7 is provided in the peripheral region RP, and is electrically connected to the first via contact electrode CP1. The second via contact electrode CP2 is also connected to the external pad PD5 through the first via contact electrode CP1. By electrically connecting the external pad PD7, the first via contact electrode CP1, the second via contact electrode CP2, and the bonding pad 55, a voltage can be supplied from the external pad PD7 to the third CMOS layer 500.

In the fifth embodiment, the same effect as in the first embodiment can be obtained.

Also, in the fifth embodiment, the second memory layer 600 is included, and the second via contact electrode CP2 has a structure that penetrates the second memory layer 600 and a part of the memory layer 200 in the Z direction. Since the second via contact electrode CP2 can form a larger diameter in the XY plane than the first via contact electrode CP1, even if a plurality of memory layers are stacked, the aspect ratio is less affected.

As the number of stacked memory layers increases, the proportion of the second via contact electrode CP2 when electrically connecting the external pad PD and the third CMOS layer 500 increases. Thus, in the present embodiment, the second via contact electrode CP2 penetrates the second memory layer 600 in the Z direction, and the proportion of the second via contact electrode CP2 is relatively large, so the resistance when supplying a voltage from the external pad PD to the third CMOS layer 500 is relatively low.

### Modification

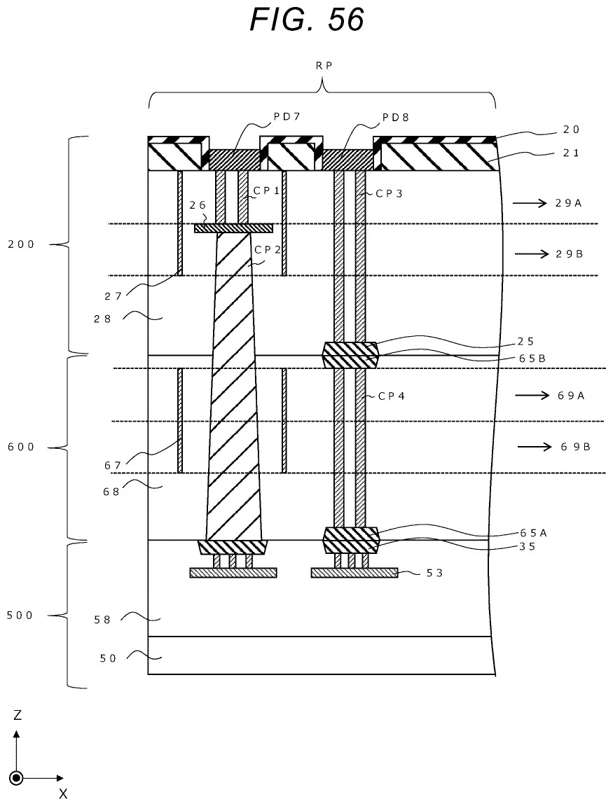

FIG. 56 is a cross-sectional view illustrating an example of a configuration of the semiconductor memory device 1 according to a modification of the fifth embodiment. Specifically, FIG. 56 illustrates the configuration of the peripheral region RP in the semiconductor memory device 1.

The semiconductor memory device 1 according to the modification of the fifth embodiment differs in that the semiconductor memory device 1 according to the fifth embodiment and the peripheral region RP are provided with the third via contact electrode CP3 and the fourth via contact electrode CP4. Since other examples of configurations may be similar to the semiconductor memory device 1 according to the fifth embodiment, descriptions thereof will be omitted.

As illustrated in FIG. 56, the external pad PD8 is provided in the peripheral region RP in the memory layer 200 and supplies a voltage to the CMOS circuit formed in the third CMOS layer 500 as well as the external pad PD7. Hereinafter, the external pads PD7 to PD8 may be described as external pads PD.

The configuration of the third via contact electrode CP3 and the fourth via contact electrode CP4 may be the same as that of the fourth embodiment, and thus the descriptions thereof will be omitted.

In the peripheral region RP of the semiconductor memory device 1 of the present modification, a plurality of external pads PD7 to PD8 are formed. The external pad PD7 is electrically connected to the third CMOS layer 500 through the first via contact electrode CP1 and the second via contact electrode CP2. The external pad PD8 is also electrically connected to the third CMOS layer 500 through the third via contact electrode CP3 and the fourth via contact electrode CP4. In other words, the voltage supply to the third CMOS layer 500 may be performed through the first via contact electrode CP1 and the second via contact electrode CP2, or may be performed through the third via contact electrode CP3 and the fourth via contact electrode CP4.

In this modification, the same effect as in the fifth embodiment can be obtained.

The electrical connection between the external pad PD and the third CMOS layer 500 is performed by two types of methods: the connection by the first via contact electrode CP1 and the second via contact electrode CP2, and the connection by the third via contact electrode CP3 and the fourth via contact electrode CP4. Therefore, in this modification, the same effect as in the modification of the third embodiment can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first stacked body in which a plurality of first conductive layers and a plurality of first insulating layers are alternately stacked in a first region in a stacking direction;
a second stacked body in which a plurality of second conductive layers and a plurality of second insulating layers are alternately stacked, the second stacked body disposed on the first stacked body in the stacking direction;
a first via contact electrode disposed in a second region adjacent to the first region, the first via contact electrode having a height that is at least half or more of a height of the first stacked body in the stacking direction; and
a second via contact electrode disposed on the first via contact electrode in the stacking direction and electrically connected to the first via contact electrode, the second via contact electrode having a height that is at least half or more of a height of the second stacked body in the stacking direction, wherein
a diameter of a surface of the second via contact electrode facing the first via contact electrode is greater than a diameter of a surface of the first via contact electrode facing the second via contact electrode.

2. The semiconductor memory device according to claim 1, wherein
when viewed from a direction orthogonal to the stacking direction, the first stacked body and the first via contact electrode overlap each other.

3. The semiconductor memory device according to claim 1, wherein
when viewed from the stacking direction, the first via contact electrode and the second via contact electrode overlap each other.

4. The semiconductor memory device according to claim 1, further comprising:
a third via contact electrode disposed in the second region and having a height that is greater than or equal to a sum of the height of the first stacked body and the height of the second stacked body in the stacking direction, wherein the third via contact electrode is spaced from the first via contact electrode and the second via contact electrode.

5. The semiconductor memory device according to claim 1, further comprising:
a first chip including the first stacked body and the second stacked body; and
a second chip bonded to the first chip at one or more bonding surfaces, wherein
the second via contact electrode penetrates the one or more bonding surfaces of the first chip and the second chip.

6. The semiconductor memory device according to claim 5, wherein
each of the first stacked body and the second stacked body includes a cell array, and
the second chip includes a first CMOS circuit.

7. The semiconductor memory device according to claim 5, wherein
the second via contact electrode has a height that is greater than a sum of the height of the second stacked body and a height of the second chip in the stacking direction.

8. The semiconductor memory device according to claim 5, wherein
the second chip includes a diffusion prevention layer provided to surround the second via contact electrode.

9. The semiconductor memory device according to claim 5, further comprising:
a third chip including a second CMOS circuit, wherein the third chip is bonded to a surface of the second chip opposite to the first chip, and
the second via contact electrode is electrically connected to the third chip.

10. The semiconductor memory device according to claim 9, wherein
the second via contact electrode has a height that is greater than a sum of the height of the second stacked body and a height of the second chip in the stacking direction.

11. The semiconductor memory device according to claim 5, further comprising:
a third via contact electrode disposed in the second region and having a height that is greater than or equal to the sum of the height of the first stacked body and the height of the second stacked body in the stacking direction, wherein
the third via contact electrode is spaced from the first via contact electrode and the second via contact electrode, and
the third via contact electrode is electrically connected to the second chip.

12. The semiconductor memory device according to claim 5, wherein
the second chip further includes a third stacked body in which a plurality of third conductive layers and a plurality of third insulating layers are alternately stacked in a third region, and a fourth stacked body in which a plurality of fourth conductive layers and a plurality of fourth insulating layers are alternately stacked, the fourth stacked body disposed on the third stacked body in the stacking direction, and
each of the first stacked body, the second stacked body, the third stacked body, and the fourth stacked body includes a cell array.

13. The semiconductor memory device according to claim 12, wherein
the second via contact electrode has a height that is greater than a sum of the height of the second stacked body, a height of the third stacked body, and a height of the fourth stacked body in the stacking direction.

14. The semiconductor memory device according to claim 1, further comprising:
a conductive layer provided between the first via contact electrode and the second via contact electrode, wherein
when viewed from the stacking direction, the conductive layer is circular or quadrilateral in shape, and
at least one of a diameter of a surface of the conductive layer when viewed from the stacking direction or a distance between opposing sides of the conductive layer when viewed from the stacking direction, is greater than or equal to the diameter of the surface of the second via contact electrode facing the first via contact electrode.

15. The semiconductor memory device according to claim 1, further comprising:
a diffusion prevention layer extending in the stacking direction and provided to surround the second via contact electrode.

16. The semiconductor memory device according to claim 1, wherein
the second via contact electrode includes a material having a resistivity lower than a resistivity of the first via contact electrode.

17. The semiconductor memory device according to claim 1, wherein
the second via contact electrode contains copper.

18. The semiconductor memory device according to claim 1, wherein
the second via contact electrode has a height that is greater than the height of the second stacked body in the stacking direction.

19. A manufacturing method of a semiconductor memory device, comprising:
forming a first stacked body to include a plurality of first sacrifice layers and a plurality of first insulating layers that are alternately stacked in a first region;
forming, in a second region adjacent to the first region, a first insulator having a height that is substantially the same as a height of the first stacked body in a stacking direction;
forming a first memory hole in the first stacked body in the first region;
forming a first via contact hole in the first insulator in the second region;
embedding a first conductor in the first via contact hole to form a first via contact electrode;
forming a second stacked body to include a plurality of second sacrifice layers and a plurality of second insulating layers that are alternately stacked on the first stacked body in the first region;
forming, on the first insulator in the second region, a second insulator having a height that is substantially the same as a height of the second stacked body in the stacking direction;
forming, in the second stacked body in the first region, a second memory hole connected to the first memory hole;
forming a second via contact hole in the second insulator in the second region; and
embedding a second conductor including a material different from the first via contact electrode in the second via contact hole to form a second via contact electrode that is electrically connectable with the first via contact electrode.

20. The manufacturing method of a semiconductor memory device according to claim 19, further comprising:
after forming the first via contact electrode and before forming the second stacked body, forming a conductive layer electrically connectable with the first via contact electrode in the second region.
